(19) United States
(12) Patent Application Publication
(10) Pub. No.: US 2007/0058753 A1
(43) Pub. Date: Mar. 15, 2007

(54) BPSK demodulator circuit using an anti-parallel synchronization loop

(76) Inventors: Carlos Saavedra, Kingston (CA); You Zheng, Kingston (CA)

Correspondence Address: Stephen J. Scribner;PARTEQ Innovations, Room 1625, Biosciences Complex, Queen's University at Kingston, Kingston, ON, K7L 3N6, CA

(21) Appl. No.: 11/512,406

(22) Filed: Aug. 30, 2006

Related U.S. Application Data
(60) Provisional application No. 60/712,127, filed on Aug. 30, 2005.

(30) Foreign Application Priority Data
Aug. 30, 2005 (CA) 2,517,641

(51) Int. Cl. H04L 27/22; H03D 3/24

(52) U.S. Cl. 375/329; 375/376

(57) ABSTRACT

An anti-parallel loop carrier synchronization circuit for coherent binary phase shift keying (BPSK) demodulation is disclosed. One embodiment comprises an anti-parallel dual phase-locked loop (PLL), which locks the carrier by its upper PLL (0°) and lower PLL (180°) alternately, according to the data bits contained in the received BPSK signal. Demodulation of the data is completed through control of the upper PLL and the lower PLL.

### RELATED APPLICATIONS

This application claims the benefit of the filing date of U.S. Patent Application No. 60/712,127, filed on Aug. 30, 2005, the contents of which are incorporated herein by reference in their entirety.

### FIELD OF THE INVENTION

This invention relates to binary phase shift keying (BPSK) based demodulators and applications thereof.

### BACKGROUND OF THE INVENTION

Binary phase shift keying (BPSK) may use either coherent or noncoherent techniques depending on the performance required and the frequency band in which the system is to work. A coherent demodulator is one in which the phase of the sinusoidal signal carrying the modulated data is determined by the demodulator circuitry and used to recover the data. Noncoherent demodulation techniques do not require any knowledge of the signal phase. Coherent BPSK has approximately a 3 dB advantage over noncoherent BPSK on bit-error-rate (BER) performance. However, coherent BPSK needs to synchronize and recover the carrier signal with a synchronization circuit in the demodulator. The squaring loop and the Costas loop are popularly used for this purpose in these systems. The difference in circuit complexity between the coherent and noncoherent BPSK becomes less important in systems working at low carrier frequency, since both can be implemented with digital techniques using high speed A/D conversion and digital signal processing (DSP) techniques. At microwave frequencies, however, the coherent method is the preferred demodulation technique since the non-coherent technique, such as differential BPSK (DBPSK), strongly depends on the DSP technique for its one-bit delay element, which cannot work at such high frequencies.

A BPSK modulator may be implemented using a multiplier to multiply the data stream with the RF carrier. In this data stream, bit 1 and bit 0 are represented by ±V₂. FIG. 2.1(a) shows a block diagram of a typical coherent BPSK modulator. An oscillator produces a pure carrier that is fed to a mixer/multiplier. Non-return to zero (NRZ) data (represented by ±V₂) are multiplied with the carrier to form the desired BPSK signal.

Assuming that the un-modulated carrier signal is represented by
C(t)=V₁ cos(ω_{c}t) (2.1)
and the NRZ data is represented by

$$D ( t ) = \{ \begin{matrix}+ {V}_{2} , when bit 1 \\ - {V}_{2} , when bit 0\end{matrix} \qquad ( 2.2 )$$

the product of the multiplier will be
S(t)=g*D(t)*C(t)=gV₁V₂ cos(ω_{c}t+φ) (2.3)
where g is the gain of the multiplier, and

$$φ = \{ \begin{matrix}0 ° , when bit 1 \\ 180 ° , when bit 0\end{matrix} \qquad ( 2.4 )$$

It can be seen that the phase of the RF carrier is shifted 180 degrees at the output of the multiplier in accordance with the NRZ data stream, which is shown in FIG. 2.1(b).

The transmitter (TX) element usually includes an amplifier, a bandpass filter and an antenna. An additional lowpass filter may be required to filter the NRZ data in order to narrow the transmitted signal spectrum.

A coherent BPSK demodulator requires carrier recovery or so-called carrier synchronization. Some variants of the phase-locked loop (PLL) were developed for this purpose and popularly used in current communications systems. One of these is called the squaring loop (FIG. 2.3), in which the incoming BPSK signal is first squared by multiplying the signal with itself to obtain a modulation-free signal at twice the carrier frequency. A PLL is then used to lock the voltage-controlled oscillator (VCO) to that modulation-free signal and thus achieve phase coherence at twice the carrier frequency. Afterward, a frequency divider is used to divide the VCO signal frequency to recover the exact carrier. After multiplying this carrier with the incoming BPSK signal, the data is recovered using a lowpass filter (LPF) to remove the high-frequency products from the multiplication.

To describe its operation, we consider the received BPSK signal with the form
S(t)=A₁ cos(ω_{c}tφ) (2.5)
where A₁ is the amplitude, ω_{c} is the carrier frequency, and the modulation phase φ bears the modulated data which has the form

$$φ = \{ \begin{matrix}0 ° , when bit 1 \\ 180 ° , when bit 0\end{matrix} \qquad ( 2.6 )$$

A squaring device such as a multiplier at the input of the squaring loop can be used to remove the modulation phase φ. Assuming the gain of the multiplier is g, the squaring term of the multiplier output will be

$${S}^{2} ( t ) = {gA}_{1}^{2} {cos}^{2} ( {ω}_{c} t + φ ) = \frac{1}{2} {gA}_{1}^{2} + \frac{1}{2} {gA}_{1}^{2} cos ( 2 {ω}_{c} t + 2 φ ) \qquad ( 2.7 )$$

where 2φ switches between 0° and 360°. Since 0° and 360° are exactly the same phase and can be ignored in the periodic trigonometric function, the 2φ term is removed from the above squaring term, resulting in

$${S}^{2} ( t ) = \frac{1}{2} {gA}_{1}^{2} + \frac{1}{2} {gA}_{1}^{2} cos ( 2 {ω}_{c} t ) \qquad ( 2.8 )$$

A band-pass filter tuned at the above double-frequency 2ω_{c} is necessary after the squaring device to remove the DC term

$$\frac{1}{2} {gA}_{1}^{2}$$

and the other harmonic products of the squaring device. Thus, the squaring process removes the data contained in the BPSK signal and produces a pure phase-coherent signal at twice the frequency of the carrier. This filtered signal at 2ω_{c} is then used as the input to the PLL operating at 2ω_{c}. The PLL is locked at this phase-coherent signal and then re-establishes the carrier phase information at twice the frequency. For a single PLL using a multiplier-type detector the locking point is located at −90° phase difference; however, demodulation using the squaring loop requires a zero phase difference between the VCO and the received carrier, so a 90° phase shifter at twice the carrier frequency is inserted in the PLL to let the VCO produce the correct phase information. The output from the squaring loop then must be frequency-divided by 2 to generate the exact phase-locked carrier for the following signal demodulation.

The demodulation of a BPSK signal becomes simple after carrier recovery. It can be done using a multiplier to multiply the recovered carrier with the received BPSK signal. Assuming the recovered phase-locked carrier has the expression
S′(t)=A₂ cos(ω_{c}t) (2.9)
then multiplication of this carrier with the received BPSK signal gives

$$S ( t ) * {S}^{′} ( t ) = {gA}_{1} {A}_{2} cos ( {ω}_{c} t ) cos ( {ω}_{c} t + φ ) = \\ \frac{{gA}_{1} {A}_{2}}{2} cos ( φ ) + \frac{{gA}_{1} {A}_{2}}{2} cos ( 2 {ω}_{c} t + φ ) \qquad ( 2.10 )$$

where g is the gain of the multiplier. Note that the above expression contains the data signal

$$D ( t ) = \frac{{gA}_{1} {A}_{2}}{2} cos ( φ ) \qquad ( 2.11 )$$

where cos(φ) switches between 1 and −1 in accordance with the NRZ data. The high frequency component in the multiplication products in equation (2.10) as well as the other harmonic products are removed by the low-pass filter at the output of the demodulator.

Although the squaring device in the squaring loop can remove the data to recover the carrier from the received BPSK signal, the received noise is also squared. For additive white Gaussian noise (AWGN), this effectively increases the noise in the loop by 3 dB. The squaring loop has a π ambiguity at its output phase because it is operating at 2ω_{c}. It cannot distinguish between π and 2π for an input phase error. Because of this, the output phase to the multiplier for data demodulation may be in error by π radians, which for BPSK would invert the sign of the data. This inversion requires an error correction, such as differential coding/decoding. The squaring loop has a further significant disadvantage, which is the need to have the PLL and its VCO running at twice the carrier frequency. This becomes a problem as the carrier frequency reaches the microwave range: it is more difficult to create a good low-noise oscillator as well as the other PLL components at such high frequencies. Furthermore, the need for a frequency divider can increase the power consumption of the circuit, since many dividers are known to sink large amounts of power.

Another circuit that is often used in phase demodulation is the Costas demodulator, developed by J. Costas (Costas, J., “Synchronous Communications,” IEEE Transactions on Communications, vol. 5, pp. 99-105, March 1957) and illustrated by the block diagram shown in FIG. 2.4. The Costas demodulator contains a dual PLL: an upper loop and a lower loop. It is usually assumed that the lower loop works as the locking loop and produces the error voltage to drive the VCO, and the upper loop demodulates the data and corrects the error voltage of the locking loop through a multiplier.

To understand its operation, we can consider the locking point on the output characteristic curve of the two phase detectors in the dual PLLs, shown in FIG. 2.5. The two circle points with zero outputs represent the locking loop's outputs at the states of bit 1 and bit 0, respectively, and the star points represent the demodulating loop's outputs. Between the two zero-output locking points, the one on the right (@ bit 0) has a negative slope and would not be a stable locking point for a single PLL with a positive gain-constant VCO. However, the Costas loop uses another multiplier to correct this point's slope by multiplying the locking loop's output with the demodulating loop's output (−k_{d}@ bit 0). The slope of this locking point is then inverted to be positive by multiplying with the negative value −k_{d}. Thus, this zero-output point (@ bit 0) becomes a stable locking point too and has the same locking characteristic as the left one (@ bit 1) due to the symmetry of the curve. Consequently, the Costas loop can provide a locking process both at the states of bit 1 and bit 0.

A brief mathematical analysis of the Costas loop is given below. It is assumed that the received BPSK signal has the form
S(t)=A₁ cos(ω_{c}t+θ₁+φ) (2.12)
where θ₁ represents the received carrier phase, and φ bears the data and alters between 0° and 180°. This received signal is multiplied respectively by A₂ cos(ω_{c}t+θ₂) and −A₂ sin(ω_{c}t+θ₂) in the two phase detectors, which are the outputs from the VCO and the 90° phase shifter respectively. The two products are

$$\begin{matrix}\begin{matrix}I ( t ) = {g}_{1} S ( t ) * {A}_{2} cos ( {ω}_{c} t + {θ}_{2} ) \\ = {g}_{1} {A}_{1} cos ( {ω}_{c} t + {θ}_{1} + φ ) * {A}_{2} cos ( {ω}_{c} t + {θ}_{2} ) \\ = {k}_{d} cos ( {θ}_{1} - {θ}_{2} + φ ) + {k}_{d} cos ( 2 {ω}_{c} t + {θ}_{1} + {θ}_{2} + φ )\end{matrix} & ( 2.13 ) \\ \begin{matrix}Q ( t ) = - {g}_{1} S ( t ) * {A}_{2} sin ( {ω}_{c} t + {θ}_{2} ) \\ = - {g}_{1} {A}_{1} cos ( {ω}_{c} t + {θ}_{1} + φ ) * {A}_{2} sin ( {ω}_{c} t + {θ}_{2} ) \\ = {k}_{d} sin ( {θ}_{1} - {θ}_{2} + φ ) - {k}_{d} sin ( 2 {ω}_{c} t + {θ}_{1} + {θ}_{2} + φ )\end{matrix} & ( 2.14 )\end{matrix}$$

where g₁ is the gain of the multipliers in the detectors and

$${k}_{d} = \frac{{g}_{1} {A}_{1} {A}_{2}}{2}$$

is the detector gain. The double-frequency terms in equation (2.13) and equation (2.14) are eliminated by the low-pass filters after the multipliers.

An error signal for the VCO control is generated by multiplying the two outputs of the detectors (the low-frequency terms in the above two equations) using another multiplier:

$${V}_{e} = \frac{{g}_{2} {k}_{d}^{2}}{2} sin [ 2 ( {θ}_{1} - {θ}_{2} ) + 2 φ ] \qquad ( \text{2.15} )$$

where g₂ is the gain of this third multiplier. Note that the data term 2φ can be eliminated in the above expression since it is either 0° or 360°. Thus, this error signal only consists of the desired term sin[2(θ₁−θ₂)] which has a positive slope when the phase error (θ₁−θ₂)=0 and can be used to drive the VCO to recover the carrier.

When the phase of the Costas loop is locked, the phase error term (θ₁−θ₂) is equal to 0. Thus, the low-frequency output term at the upper loop becomes

$$I ( t ) = \frac{{A}_{1} {A}_{2}}{2} cos ( φ ) \qquad ( \text{2.16} )$$

which carries the demodulated data.

In the above analysis, the upper loop was assumed to work as the demodulating loop and the lower loop as the locking loop. This, however, is not always the case. The locking and demodulating functions will be reversed between these two loops if the initial phase of the VCO changes 90° relative to the carrier phase. This may occur at the beginning of the demodulation operation, or in the re-locking process caused by large phase noise in the received BPSK signal. Thus, the receiver requires a decision circuit to determine which loop outputs the demodulated data. Costas used a summer to sum the two detector outputs to overcome this problem. The switching of the functions between the two loops also causes an inversion on the data output, which the summer cannot recognize. Therefore, similar to the squaring-loop demodulator, a demodulator using the Costas loop also requires an error correction to solve this data inversion.

The Costas demodulator uses two PLL circuits in parallel that are 90° out of phase, and a third multiplier circuit. The need for a 90° phase shift requires the use of either a phase shifter circuit, or a quadrature VCO. In either case, the result of the added components is increased complexity, size, and power consumption.

### SUMMARY OF THE INVENTION

In a first aspect the invention provides a BPSK demodulator for use with a BPSK signal. The demodulator includes a first phase-locked loop for locking to the BPSK signal and a second phase-locked loop for locking to the BPSK signal. The second phase-locked loop locks to the BPSK signal at a 180° phase difference from the first phase-locked loop. The first phase-locked loop and the second phase-locked loop are selected such that the first phase-locked loop is in lock at 0° and the second phase-locked loops is in lock at 180°.

The demodulator may also include a selection network for selection of the first and second phase-locked loops. The selection network may have two switches, a comparator, and an inverter. In another embodiment the selection network may have two switches and a differential comparator. The selection network may have a low-pass filter.

The first and second phase-locked loops may each include a multiplier, or a multiplier and a voltage controlled oscillator. The first and second phase-locked loops may each include a low pass filter and a summing circuit or a voltage summer. The voltage summers may be placed either before or after the low pass filters. A DC offset may be introduced into each phase-locked loop by the voltage summer such that the phase-locked loops have different detected voltage outputs. The first and second phase-locked loops may be interconnected to share a single voltage controlled oscillator.

The demodulator may include an automatic gain control circuit front end. The demodulator may include an automatic gain control circuit at its input and an error correction at its output. The demodulator may include a voltage summer at the VCO front end. The demodulator may include a voltage summer and a voltage attenuator at the VCO input. The first and second phase-locked loops may each include an amplifier. The first and second phase-locked loops may each include an attenuator.

The demodulator may be implemented in an integrated circuit. The two multipliers in the detectors may share a current mirror for their DC bias. The two voltage summers may also share a current mirror to combine the DC offsets of the two phase-locked loops. The 180° phase shifter may be implemented using a twisted connection.

In a second aspect the invention provides a method of demodulating a BPSK signal. Preferably, the demodulation is coherent. The method provides a first phase-locked loop for locking to the BPSK signal, and a second phase-locked loop for locking to the BPSK signal. The second phase-locked loop locks to the BPSK signal at a 180° phase difference from the first phase-locked loop. The method also comprises selecting the phase-locked loops such that the first phase-locked loop is in lock at 0° and the second phase-locked loop is in lock at 180°.

Selecting the phase-locked loops may include comparing the BPSK signal detected by each of the phase-locked loops to determine the phase of the BPSK signal. Selecting the phase-locked loops may include comparing the outputs of the two phase locked loops to determine the phase of the BPSK signal, or the contained data bit. Selecting the phase-locked loops may include opening and closing respective switches in accordance with the determined phase.

The method may include detecting the phase of the BPSK signal in each of the phase-locked loops by multiplying the BPSK signal and a locking signal produced by a voltage controlled oscillator. Detecting the phase may include passing the multiplied signal through a low pass filter and a summing circuit or a voltage summer.

The method may include producing the locking signal for both detectors using a single voltage controlled oscillator.

Other aspects, including further demodulators and methods, are evident from the detailed description and figures provided herein.

### BRIEF DESCRIPTION OF THE DRAWINGS

For a better understanding of the invention and to show more clearly how it may be carried into effect, reference will now be made, by way of example, to the accompanying drawings which show preferred embodiments of the invention, or prior art where indicated, and in which:

FIG. 2.1(a) shows a block diagram of a typical coherent BPSK modulator.

FIG. 2.1(b) shows that in the modulator of FIG. 2.1(a) the phase of the RF carrier is shifted 180 degrees at the output of the multiplier in accordance with the NRZ data stream.

FIG. 2.3 shows a BPSK demodulator using a squaring loop.

FIG. 2.4 shows a BPSK demodulator using a Costas loop.

FIG. 2.5 shows the output characteristic of the detector and the locking process for the phase-locked loop of FIG. 2.4.

FIG. 3.1 shows an anti-parallel loop with two interconnected phased locked loops in accordance with a preferred embodiment of the invention.

FIG. 3.2 shows a circuit diagram of an embodiment of the BPSK demodulator of FIG. 3.1.

FIG. 3.3 shows the output characteristic of the detectors and the locking process of the BPSK demodulator of FIG. 3.2.

FIG. 3.4 shows the circuit diagram of the BPSK demodulator of FIG. 3.2 with mathematical analysis.

FIG. 4.1 shows a model of the demodulator of FIG. 3.1 for use in simulations.

FIG. 4.2 shows BPSK signal generation for simulations using the model of FIG. 4.1.

FIG. 4.3(a) shows PRBS data for simulations using the model of FIG. 4.1 and the BPSK signal generation of FIG. 4.2, where the initial phase difference between the VCO and the input carrier is θₑ=60°.

FIG. 4.3(b) shows outputs of the LPFs in the simulation of FIG. 4.1 using the PRBS data of FIG. 4.3(a) and its phase configuration.

FIG. 4.3(c) shows outputs of phase detectors (after the voltage summers) in the simulation of FIG. 4.1. using the PRBS data of FIG. 4.3(a) and its phase configuration.

FIG. 4.3(d) shows demodulated PRBS data with inversion (after the comparator) in the simulation of FIG. 4.1. using the PRBS data of FIG. 4.3(a) and its phase configuration.

FIG. 4.7 shows a more detailed experimental embodiment of the demodulator of FIG. 3.1.

FIG. 4.8 (a) shows experimental results at outputs of the detectors in the embodiment of FIG. 4.7 for V_{dc}=0.5 V (after the two amplifiers).

FIG. 4.8(b) shows further experimental results including the PRBS data for BPSK signal generation (Channel 1) and the demodulated data (Channel 2).

FIG. 5.1 shows a BER versus Eb/No curve for different DC offset values using the experimental circuit of FIG. 4.7.

FIG. 5.2 shows phase detector output characteristic curves before the voltage summers.

FIG. 5.3(a) shows spikes at the outputs of the switches in simulations where V_{dc}=0.3 V.

FIG. 5.3(b) shows spikes at the output of switches in the experiment where V_{dc}=0.5 V.

FIG. 5.4 shows data inversions induced by large spikes in simulations (for cos(Oe)>0).

FIG. 5.5 shows a further embodiment of the BPSK demodulator of FIG. 3.1 incorporating spike suppression.

FIG. 5.6 shows simulation results with spike suppression for the circuit of FIG. 5.5 (for cos(θₑ)>0).

FIGS. 6.1(a) and (b) show embodiments of the BPSK demodulator used in monolithic microwave integrated-circuit (MMIC) simulation and fabrication, respectively.

FIG. 6.2 shows an IC implementation of the multiplier and the voltage summer in each phase detector of the MMIC demodulator of FIG. 6.1(a) and (b).

FIG. 6.3(a) shows example waveforms from a Gilbert multiplier (the two large signals with 90° phase difference) and the output of a voltage summer in the circuit of FIG. 6.2 in the case of 0 V offset from the voltage summer.

FIG. 6.3(b) shows example waveforms from a Gilbert multiplier (the two large signals with 90° phase difference) and the output of a voltage summer in the circuit of FIG. 6.2 in the case of 0.1 V DC offset from the voltage summer.

FIG. 6.4 shows an embodiment of a current mirror shared by the two voltage summers in the MMIC demodulator of FIG. 6.1(a) and (b).

FIGS. 6.5(a) and (b) show embodiments of a complementary differential VCO used in the MMIC demodulator simulation and fabrication, respectively.

FIGS. 6.7(a) and (b) show embodiments of an NMOS switch and differential comparator used in the MMIC demodulator simulation and fabrication, respectively.

FIG. 6.11 shows the measurement setup for the MMIC BPSK demodulator of FIG. 6.1(b).

FIGS. 6.13(a), (b), and (c) show the original data at 200 Kbps, 1 Mbps, and 5 Mbps, respectively (upper waveform) and the demodulated data (lower waveform) of the MMIC demodulator of FIG. 6.1(b).

FIG. 6.14 shows an embodiment of a multi-band MMIC implementation of the BPSK demodulator of FIG. 3.1.

### DETAILED DESCRIPTION OF PREFERRED EMBODIMENTS

The invention provides a novel circuit to demodulate, or extract, the modulated data from a BPSK-modulated carrier. With easily-integrated characteristics, demodulators of the invention may be used in, for example, INMARSAT™ systems, global positioning systems (GPS), radio frequency identification (RFID) systems, and next-generation digital radio systems.

As used herein, the term “data” is intended to refer to the information or data, which may be digital, which is modulated in a BPSK signal and recovered or demodulated by a BPSK demodulator circuit of the invention. The terms “demodulator” and “demodulator circuit” are used throughout this disclosure and are intended to be equivalent.

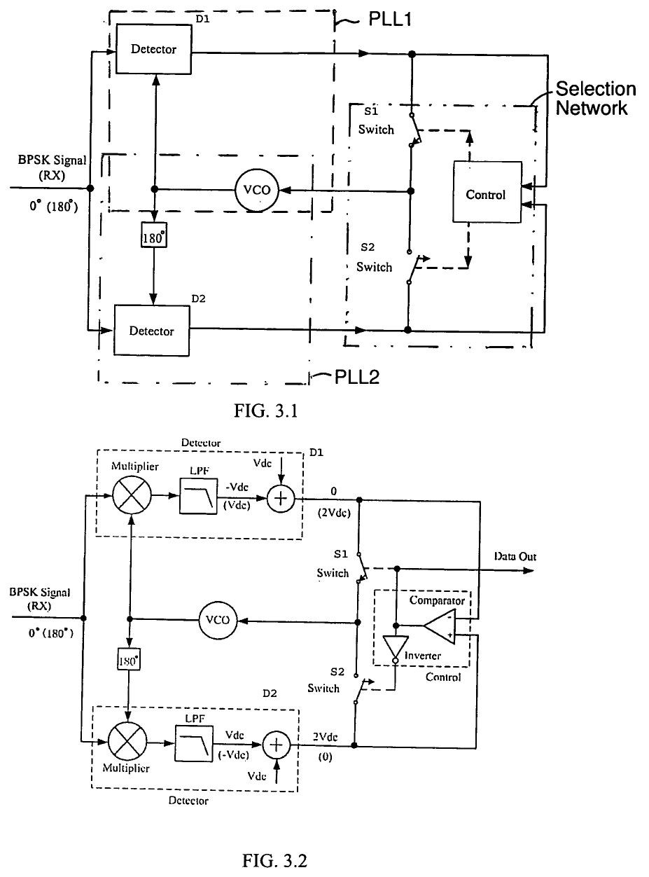

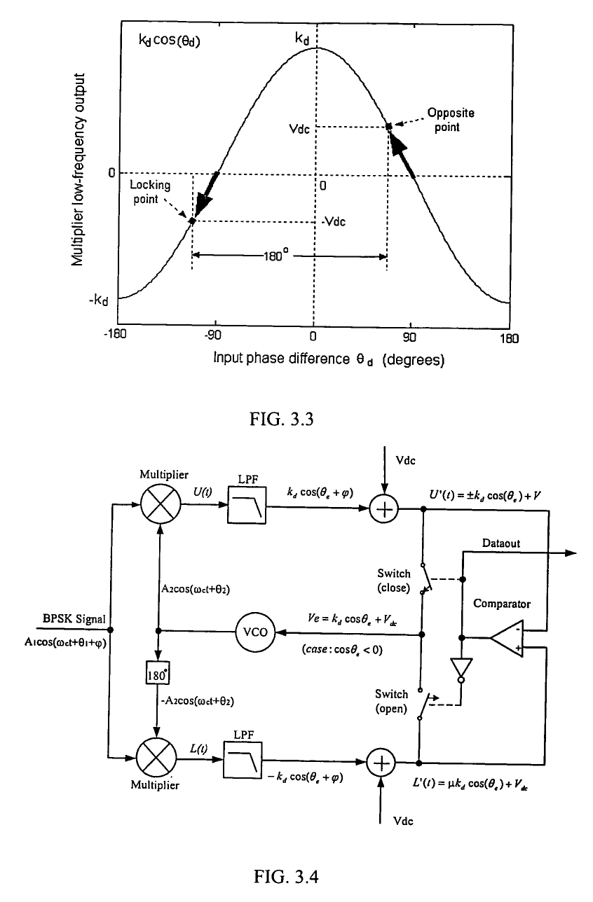

Referring to FIG. 3.1, the preferred embodiment of the circuit uses two parallel phase-locked loops (PLLs) in which only one of the loops is in lock at any given time. One loop is in phase with the carrier at 0° while the other loop is 180° out of phase. If the incoming BPSK signal is at 0°, then the in-phase PLL will be in lock. When the incoming BPSK signal changes phase from 0° to 180°, the loop with the 180° phase shift will then come into lock and the other PLL will be out of lock. A decision mechanism or selection network comprising, for example, a comparator circuit decides whether the 0° or the 180° PLL is in lock and from this the original data is recovered. This is demonstrated herein in simulations, experiments with a discrete component demodulator, and measurements of a fabricated demodulator IC.

The circuit achieves very high data rates because the time it takes for the PLLs to achieve lock when there is a transition in the phase of the carrier from 0° to 180° is very small, since the loop that is out of lock is in ‘stand-by’ mode, ready to achieve lock when the incoming signal changes phase. Modulation-demodulation systems and bit error rate (BER) measurements were used to demonstrate performance of the circuit. In the BER measurement, a very long stream of random bits (e.g., 2²³) was sent through the transmitter and then recovered at the receiver using the demodulator circuit. As discussed below, very low error rates were achieved.

Referring to FIG. 3.1, an anti-parallel loop for coherent BPSK carrier synchronization uses two PLLs with 180° phase difference, resulting in an anti-parallel loop structure. The PLLs are interconnected such that the locking function alternates between both PLLs according to a selection network that recognizes the phase of the incoming BPSK signal. This can be contrasted with the prior quadrature (90 degree phase shift) loop structure in the Costas loop discussed previously.

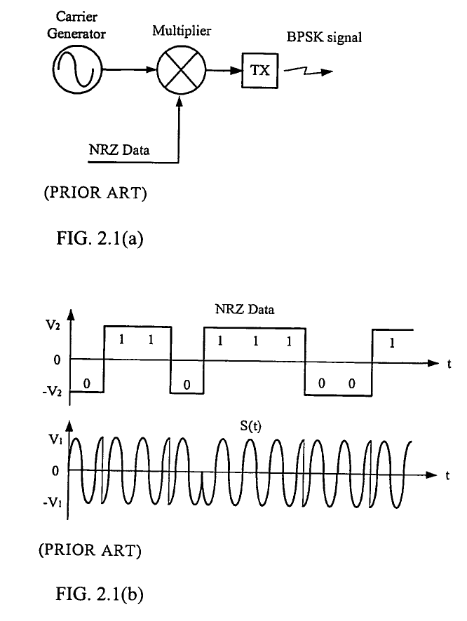

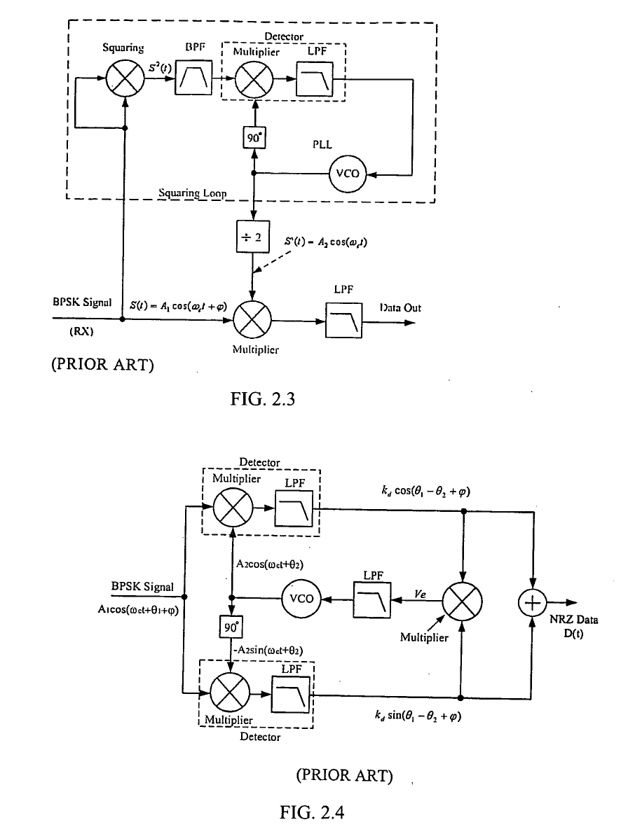

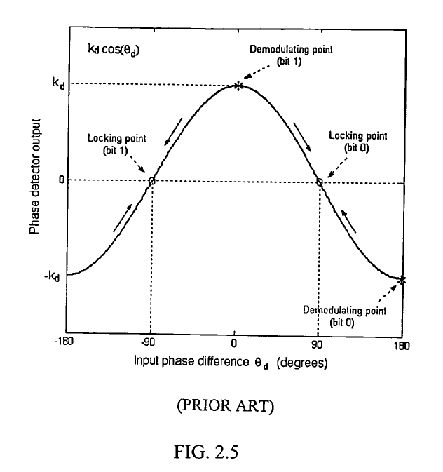

The Costas loop (FIG. 2.4) uses two PLL circuits in parallel, but 90° out of phase. The need for a 90° phase shift requires the use of either a special phase shifter circuit in the Costas Loop, or a quadrature VCO. In either case, the result is an increase in complexity and size, and power consumption if a quadrature VCO is used. By contrast, in the demodulator of the invention (e.g., FIG. 3.1), since only a 180° shift is required, a compact differential VCO may be used. Also, in a preferred embodiment, the demodulator of the invention only requires two multipliers for its detectors compared to three multipliers required in the Costas loop, which further lowers circuit complexity and power consumption.

1. Circuit Description and Analysis

As shown in FIG. 3.1, the anti-parallel loop may be implemented using two interconnected PLLs (PLL1, PLL2, also referred to herein as the upper loop and lower loop, respectively) that share a VCO, with a 180° phase shifter in the lower loop and two switches with their control circuit at the VCO input. It is well known that a single PLL can lock to a pure carrier signal without phase switching. With proper control of the switches, an anti-parallel loop with 180° phase difference can similarly provide the locking to a received BPSK signal, which switches its phase between 0° and 180°. For example, when the received BPSK signal is at 0° phase, the upper switch S1 closes and the lower switch S2 opens, and therefore the detector output of the upper loop is fed to the VCO and it operates like a single PLL for the locking. When the received BPSK signal switches its phase to 180°, the upper switch S1 opens and the lower switch S2 closes, and thus the lower loop operates as the locking loop. Since the two loops have 180° phase difference which corresponds to the BPSK signal phase switching difference, the VCO phase will remain stable during switching of the locking between these two loops, and the VCO output will therefore recover the carrier.

Proper control of the switches S1, S2 is desired for the above operation of the anti-parallel loop. The control circuit of the switches has two inputs and requires a voltage difference between these two inputs in order to produce the proper control signal. If, for example, multiplier-type detectors are used and the upper loop PLL1 was assumed to lock, the upper detector D1 outputs zero. It is assumed that the carrier frequency is equal to the centre frequency of the VCO here and in the following description and analysis. The case where they are not equal will be discussed in the mathematical analysis below. The phase difference between the two inputs of the upper detector D1 is −90° at this time. At the same time, due to the 180° phase shifter in the lower loop PLL2, the phase difference for the lower detector D2 is 90° and also has zero output. Because the inputs of the control circuit come from these two detector outputs, the control circuit would fail to distinguish these two zero inputs and give the proper control signal for the switches.

Two multiplier-type detectors with DC offsets can produce the desired different outputs in this anti-parallel loop and meet the above requirement. FIG. 3.2 shows a detailed circuit diagram of such a BPSK demodulator based on the anti-parallel method, where a DC offset V_{dc} is introduced into each detector D1, D2 using a voltage summer, and the control circuit is realized using a comparator and an inverter. The control circuit may also be realized using a fully differential comparator, which will be discussed below in the IC implementation of the demodulator. To explain the operation of this embodiment we assume the upper switch S1 closes (the lower switch S2 opens) and the upper loop PLL1 works as locking loop first. When the upper loop is locked, the VCO's phase is driven to let the upper detector D1 output a zero voltage. That is, a −V_{dc} DC voltage has to be produced from the upper multiplier-type detector D2 (excluding the voltage summer), in order to cancel the DC offset V_{dc} introduced by the upper voltage summer. At the same time, the voltage from the lower multiplier-type detector D2 is V_{dc} due to the 180° phase difference between the two loops. As a result, the output of the lower voltage summer will be 2V_{dc}, which is also the lower detector output. Thereafter, this 2V_{dc} voltage output at the lower loop PLL2 and the zero output at the upper loop PLL1 are fed to the comparator in the control circuit together to produce a positive signal to close the upper switch S1 (the inverter produces an inverted signal to open the lower switch S2). These switch states are exactly what we assumed at the beginning. When the phase of the received BPSK signal switches 180°, the upper detector D1 outputs 2V_{dc} and the lower detector D2 outputs zero. Therefore the control signal after the comparator is inverted, which turns on the lower switch S2 and turns off the upper switch S1, and then the lower detector's output (zero) is fed to the VCO to lock its phase.

The output of the lower multiplier-type detector V_{dc}, relative to the output of the upper detector −V_{dc} in the first case above, is shown in FIG. 3.3. This figure shows the multiplier-type detector output versus its two-input phase difference. The output of the upper multiplier-type detector D1 is pushed from the zero point on the left to −V_{dc} (the locking point) by the upper DC offset V_{dc}. Now let's consider the lower multiplier-type detector D2. Its phase state is located at the opposite point shown in FIG. 3.3, which is 180° away from the locking point of the upper multiplier-type detector. Since this detector output curve is a symmetric cosine function, the opposite point will be at the point with voltage inverted to that of the locking point, i.e. V_{dc}.

Note that the input of the VCO remains at zero when the received BPSK signal switches its phase, so the VCO phase remains stable and the input phase difference (θ_{d}) of the detector stays at the locking point. Therefore, the data contained in the BPSK signal is removed by switching the locking loop between the two loops and the carrier is recovered. It should be also noted that the control signal from the comparator for loop switching is exactly the demodulated data signal, so a coherent BPSK demodulator is realized based on the anti-parallel method illustrated in FIG. 3.2.

Let's assume again that the received BPSK signal has the form
S(t)=A₁ cos(ω_{c}t+θ₁+φ) (3.1)
where θ₁ represents the received carrier phase, and φ bears the data and switches between 0° and 180°. This received signal is multiplied by A₂ cos(ω_{c}t+θ₂) and −A₂ cos(ω_{c}t+θ₂), which are the outputs from the VCO and the 180° phase shifter (see the redrawn circuit diagram of the BPSK demodulator in FIG. 3.4). The carrier frequency is equal to the centre frequency of the VCO in this analysis. The case that they are not equal will be discussed at the end of this analysis. The products of the two multipliers are

$${k}_{d} = \frac{{A}_{1} {A}_{2}}{2}$$

Where the multipliers are assumed to have a unit gain to simplify the analysis,

$$\begin{matrix}\begin{matrix}U ( t ) = S ( t ) * {A}_{2} cos ( {ω}_{c} t + {θ}_{2} ) \\ = {A}_{1} cos ( {ω}_{c} t + {θ}_{1} + φ ) * {A}_{2} cos ( {ω}_{c} t + {θ}_{2} ) \\ = {k}_{d} cos ( {θ}_{e} + φ ) + {k}_{d} cos ( 2 {ω}_{c} t + {θ}_{1} + {θ}_{2} + φ )\end{matrix} & ( \text{3.2} ) \\ \begin{matrix}L ( t ) = - S ( t ) * {A}_{2} cos ( {ω}_{c} t + {θ}_{2} ) \\ = - {A}_{1} cos ( {ω}_{c} t + {θ}_{1} + φ ) * {A}_{2} cos ( {ω}_{c} t + {θ}_{2} ) \\ = - {k}_{d} cos ( {θ}_{e} + φ ) - {k}_{d} cos ( 2 {ω}_{c} t + {θ}_{1} + {θ}_{2} + φ )\end{matrix} & ( \text{3.3} )\end{matrix}$$

is the phase detector gain and θₑ=θ₁−θ₂ is the initial phase difference between the carrier and the VCO. The double-frequency terms in equations (3.2) and (3.3) are eliminated by the low-pass filters. After the low-pass filters, the two low-frequency signals enter the voltage summers and sum with the DC offsets, which results in:
U′(t)=k_{d} cos(θₑ+φ)+V_{dc}=±k_{d} cos(θₑ)+V_{dc} (3.4)
L′(t)=−k_{d} cos(θₑ+φ)+V_{dc}=∓k_{d} cos(θₑ)+V_{dc} (3.5)
where the data φ alternates between 0° and 180′, resulting in a “±” sign for the cosine functions. As we can see, the two outputs in equations (3.4) and (3.5) alternate oppositely between two voltage values:
V₁=k_{d} cos(θₑ)+V_{dc} and V₂=−k_{d} cos(θₑ)+V_{dc} (3.6)
The configuration of the control circuit in the anti-parallel loop only allows the detector output with the smaller value to pass the switches and enter the VCO. If the initial value of cos(θₑ) before locking is negative, the first value V₁ above is the smaller one and it is selected as the error voltage Vₑ to drive the VCO regardless of which loop it is from. Then the error voltage fed to the VCO will be
Ve=V₁=k_{d} cos(θₑ)+V_{dc} (3.7)
where the data φ or the “±” sign in equations (3.4) and (3.5) is eliminated by the control of the switches, as described above. Thus, the VCO phase will remain stable when the phase of the received BPSK signal is switched in accordance with the data. When the VCO is locked, its input error voltage is Ve=V₁=0, which, according to equation (3.7), results in

$${θ}_{e} = {cos}^{- 1} ( - {V}_{dc} / {k}_{d} ) = - \frac{π}{2} - ϕ \qquad ( \text{3.8} )$$

where φ=sin⁻¹(V_{dc}/k_{d}). This result is consistent with the location of the locking point in FIG. 3.3. Substituting the θₑ value in the expression of V₂ in equation (3.6) yields the demodulating loop's detector output:
V₂=−k_{d} cos(θₑ)+V_{dc}=V_{dc}+V_{dc}=2V_{dc} (3.9)
The V₂ (i.e., 2V_{dc}) and V₁ (i.e., 0) are then fed to the comparator to produce the data output and the control signal.

In the above analysis, the VCO is locked to the upper loop at bit ‘I’ and to the lower loop at bit ‘0’ as the result of cos(θₑ)<0. However, if the initial value of cos(θₑ) before locking is positive, the locking state in the above case will be reversed, i.e., V₂ is the smaller one and is chosen for the error voltage to drive the VCO. When the VCO is locked, Vₑ=V₂=0, and the phase difference between the carrier and the VCO is

$${θ}_{e} = \frac{π}{2} - ϕ \qquad ( \text{3.10} )$$

Now the VCO is locked to the lower loop at bit ‘1’. Since there is an additional 180° phase introduced from the phase shifter to the lower loop, the phase difference between the lower detector inputs in this case is

$${θ}_{d} = π - {θ}_{e} = - \frac{π}{2} - ϕ \qquad ( \text{3.11} )$$

It is still at the same location (the locking point in FIG. 3.3) as in the previous case. Substituting equation (3.10) into equation (3.6) results in V₁=2V_{dc}. In this case, the output of the comparator is zero in order to turn on the lower switch S2, which results in an inversion on the data output compared to the last case. Thus, the anti-parallel loop also requires correction of the data inversion.

The two DC offsets are assumed to be the same in the above description of the operation and in the analysis. The demodulator of the invention works when there is a difference between the two DC offsets, which often arises from variation in element values during manufacturing. In this case, the detector of the demodulation loop will output (V_{dc1}+V_{dc2}) instead of 2V_{dc}, where V_{dc1} and V_{dc2} represents the two different DC offsets. The detector output of the locking loop maintains zero in this case. Moreover, if there is a small deviation of the carrier frequency of the input BPSK signal from the centre frequency of the VCO, the detector of the locking loop will output a small error voltage of δ when the loop is locked, and the detector output of the demodulation loop becomes (2V_{dc}−δ), or (V_{dc1}+V_{dc2}−δ) if the two DC offsets are different. Note that the two detectors still have different outputs to ensure the demodulator operation until δ exceeds V_{dc}, or (V_{dc1}+V_{dc2})/2 for the case of the different DC offsets.

The embodiments described herein provide a novel synchronization method for a BPSK demodulator, which contains an anti-parallel loop and two switches in the control circuit. The functional description of the demodulator and the mathematical analysis above indicate that the demodulator can recover the carrier and demodulate the data properly. The introduced DC offset determines the output level of the two detectors.

2. Circuit Demonstrations

The BPSK demodulator of the invention was demonstrated in simulations, in implementations with a discrete component demodulator, and in a fabricated integrated circuit demodulator.

2.1. Simulation

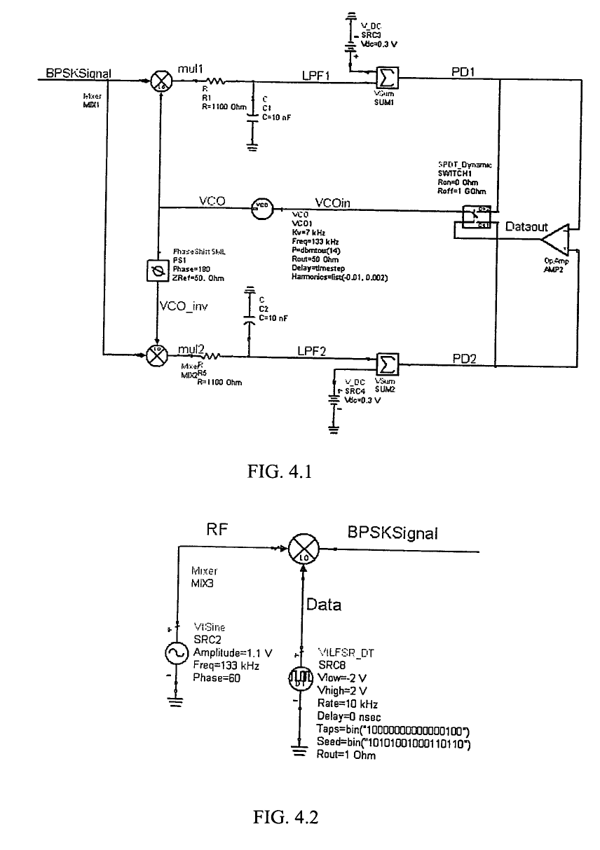

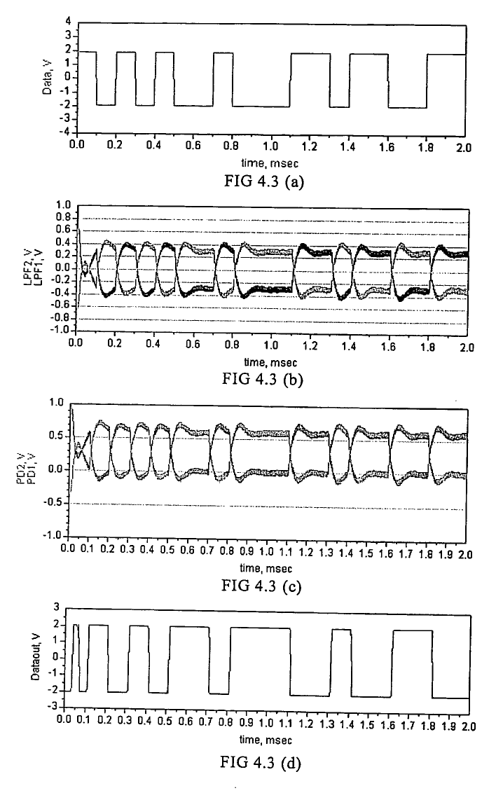

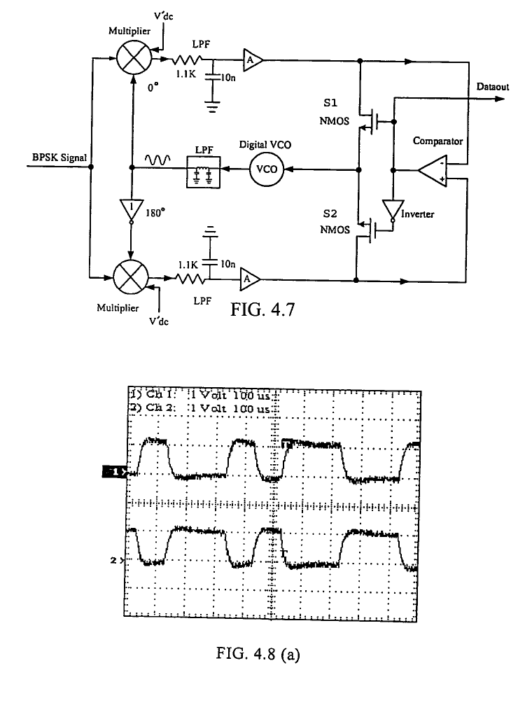

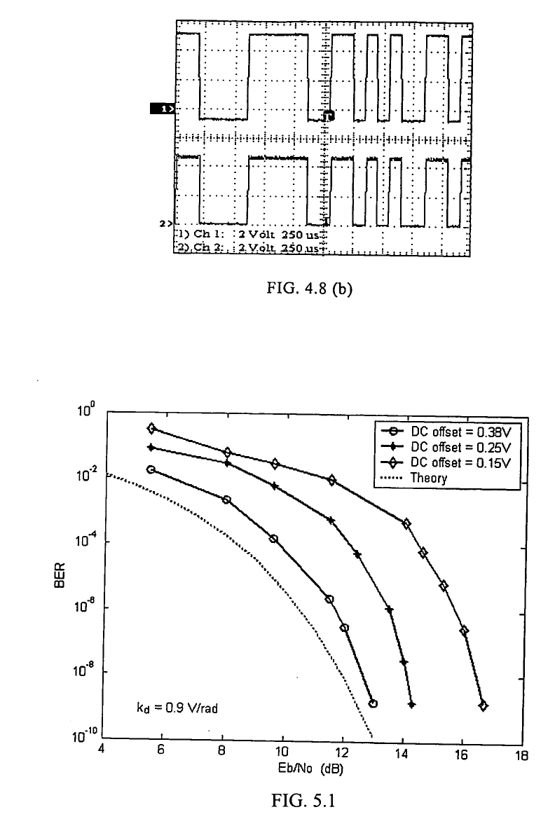

The BPSK demodulator was simulated in the electronic design automation software Advanced Design System (ADS), based on its system-level components, as shown in FIG. 4.1. The center frequency (i.e., carrier frequency) of the VCO was set to 133 kHz, which was consistent with the frequency of the VCO in the discrete component demodulator implementation. However, microwave frequency was used for the monolithic microwave integrated circuit (MMIC) implementation of the demodulator, described below. Other features of the VCO in the simulation are given below:

Gain Constant: 14π KradNolt

Output Power: 14 dBm

which were also consistent with those in the discrete component demodulator. An ideal 180° phase shifter was chosen in this simulation. Two simple RC low-pass filters (LPFs) were used for the loop filters in the phase detectors. The cutoff frequency of the LPFs was chosen according to the data rate to avoid inter-symbol interference (ISI) and to have good noise performance at the same time. In view of the low carrier frequency of 133 kHz, a data rate of 10 Kbps was used in these simulations, and a cutoff frequency of 14.4 kHz was chosen for the two LPFs. Another consideration for the PLL is the damping factor. An optimized damping factor is about 0.7. Therefore, the multipliers in the phase detectors had the following parameters:

Input power: 14 dBm

Output signal: double-sideband

Conversion Gain: −7 dB

which resulted in a gain of K_{d}=1 V/rad for the phase detectors and thus 0.72 for the damping factor. The voltage summers for the DC offsets were implemented using two ideal voltage summers. An IC design of these voltage summers will be discussed later in this description. The switches after the voltage summers utilized a single-pole double-throw switch, which had the same function as that of the two switches S1, S2 in the above description. This switch was controlled by a comparator implemented using an operational amplifier (OPAMP) and provided proper switching operation for this demodulator.

The modulated BPSK signal used in the simulations came from a multiplication of a carrier source at 133 kHz and a pseudo-random pulse sequence (PRBS) data at 10 kbps, see FIG. 4.2.

The simulations were carried out with different carrier phases while the VCO initial phase was fixed in order to observe the locking processes in all initial phase differences between the VCO and the carrier. The initial phase of the VCO was θ₂=0° in the simulations while the phases of the carrier were chosen as θ₁=60°, 130°, 220°, and 300°, which were in the four phase quadrants, respectively. They resulted in the initial phase differences θₑ=θ₁−θ₂=60°, 130°, 220°, and 300°, which covered all the cases for cos(θₑ)>0 and cos(θₑ)<0 discussed previously. The DC offsets were V_{dc}=0.3 V.

The simulation results for the case of θₑ=60° are presented in FIG. 4.3. As can be seen, the outputs of the two LPFs were ±V_{dc}=±0.3V alternately (FIG. 4.3(b)), and the detector outputs (after the voltage summers) alternated between 0 V and 2V_{dc}=0.6V (FIG. 4.3(c)), which were expected from the analysis provided previously. These outputs were accompanied with small signal components at 266 kHz coming from the multiplication. Furthermore, there were small overshoots after the transitions of these outputs, which were determined by the damping factor of the PLL. The PRBS data was demodulated successfully with an inversion. This result had been predicted in the second case of the mathematical analysis provided above, i.e. in the case of cos(θₑ)>0. As discussed previously, the inversion is common in phase demodulations and may be corrected, e.g., by using additional differential coding/decoding. A locking process at the beginning of the demodulated data caused a sharp transient; however, this is not a problem in communication systems, since a testing data sequence is usually sent before the locking is set up.

Simulation results with other initial phase differences, including θₑ=130°, 220°, and 300° were also obtained. The locking operation performed well and the demodulator recovered the PRBS data properly in all these cases. Furthermore, with the 300° initial phase difference there was an inversion of the demodulated data, also because of the initial positive cos(θₑ) value, while the 130° and 220° results had non-inverted demodulated data due to the initial negative cos(θₑ) value.

More simulations with different values of θₑ from the above four cases were also conducted and the results agreed with these four cases and the analysis provided previously, and verified the proper operation of the BPSK demodulator.

2.2. Discrete Component Implementation

Based on the above simulations, a circuit was built using packaged integrated circuit components (see FIG. 4.7). Two four-quadrant analog multipliers were chosen for the phase detectors, which had an additional summing input and were utilized for the voltage summers for the DC offsets needed in this demodulator. The VCO was implemented with a digital VCO with a low-pass filter at its output to reject the harmonics and produce a sinusoidal signal. Its center frequency was 133 kHz and the measured gain constant was 14π Krad/volt. An amplifier with an inversion and unit gain was used for the 180° phase shifter. The cutoff frequency of LPFs for the loop filters was 14.4 kHz, the same value used in the simulation. The loss of the multiplier ICs used was large (20 dB) and resulted in a very small detector gain k_{d}. Therefore, to achieve the same optimal damping factor of 0.7 as the simulation, an amplifier A was introduced in each loop to compensate for the loss of the multipliers. The detector gain k_{d} (including the gain of the amplifier) was measured to be 0.9 V/rad in the experiments, close to that in the simulations. The switches S1, S2 were implemented with two N MOSFETs controlled by the signals from a comparator circuit and an inverter. The configuration of the switches using N-type MOSFETs will be further discussed later in this description.

The BPSK signal generator used for the verification test was similar to the setup in the simulations. A multiplier circuit was used to multiply a carrier signal (133 kHz) with a pseudorandom binary sequence (PRBS) non-return to zero (NRZ) data (10 Kbps) from a Hewlett Packard 3764A digital transmission analyzer (DTA). The NRZ data from the DTA was transformed to a symmetrical signal (±2 V) as required by the multiplier.

A DC voltage V_{dc}′=0.04V was fed to the summing input of each multiplier in the test, which would be equivalent to a DC offset V_{dc}=0.5V after the amplifier A (considering the amplifier as part of the detector). FIG. 4.8 presents the experimental waveforms captured from the test. FIG. 4.8(a) gives the outputs of the two detectors. Note that the two outputs offset with each other and their voltage levels were 0 V and 2V_{dc}=1 V, which were expected according the analysis provided previously. FIG. 4.8(b) gives the modulating PRBS data (Channel 1) used for the test and the successfully-demodulated data (Channel 2) from the BPSK demodulator.

It should be pointed out that the waveforms shown in FIG. 4.8(a) and FIG. 4.8(b) were captured at different times and thus contained different data (the PRBS data varies with time). The case where the demodulated data contained an inversion of the modulating PRBS data was also observed occasionally when the circuit was reset in the experiments. The experiments were in accordance with the analysis of the locking processes concerned with the initial phase differences as discussed previously. Simulations and experiments were also carried out with small deviations in the carrier frequency or with two different DC offsets for the two loops as discussed above, and in all cases the demodulator performed flawlessly.

The simulation results discussed above illustrate the different locking processes of the demodulator of the invention in respect of all possible initial phase differences between the VCO and the carrier in the received BPSK signal, which were expected from the mathematical analysis discussed previously. The implementation after the simulations confirmed the locking processes. Moreover, the results from the simulation and the implementation demonstrated the relationship between the detector outputs and the introduced DC offsets in the detectors, and the role of the DC offset in the demodulator. Noise performance of the demodulator system may depend on the DC offset, which will be discussed below.

2.3. Further Design Considerations with Simulations and Implementations

An embodiment using automatic gain control (AGC) will now be described. In the demodulator shown in FIG. 3.2, the dual anti-parallel loop locked to the BPSK signal (two phase states) may be regarded as a single PLL locked to a pure carrier, given ideal switching operation of the switches. Thus, design issues for the phase-locked loop may also be applied to the dual loop. The optimal condition for a PLL is a damping factor of about 0.7, as determined by the detector gain, the gain constant of the VCO and the cutoff frequency of the loop filter, according to the equation below:

$$ξ = \sqrt{\frac{{ω}_{L}}{4 {k}_{d} {k}_{o}}} = \sqrt{\frac{{ω}_{L}}{4 k}} \qquad ( \text{5.1} )$$

where k=kₒk_{d} is the loop gain. The performance of the phase detector is related to the detector gain k_{d}. It is defined as:
k_{d}=v_{d}/θ_{d} (5.2)
where v_{d} is the voltage output and θ_{d} is the phase difference between the two input signals. As discussed previously, for a multiplier-type detector, since the output versus the input phase difference is a cosine function, the detector gain may be approximated to the slope at the locking point when the loop is locked:

$${k}_{d} = \frac{g {A}_{1} {A}_{2}}{2} \qquad ( \text{5.3} )$$

where the detector gain is determined by the multiplier gain g and the two inputs' amplitudes, A, and A₂. Thus, to keep the detector gain k_{d} constant for an optimal damping factor, the received BPSK signal amplitude and the VCO's output amplitude are required to remain stable at all times. A stable BPSK signal can be achieved by an automatic-gain-control (AGC) circuit before the BPSK demodulator.

Gain constant is important to the VCO and can be defined as:

$${k}_{o} = \frac{Δω}{Δ {v}_{d}} \qquad ( \text{5.4} )$$

where ω is the angular frequency of the VCO output and v_{d} is the VCO control voltage coming from the phase detector. An ideal VCO has a constant kₒ, which indicates linear frequency tuning for the VCO and ensures a constant damping factor in the phase locking process. However, in a practical circuit, such as a VCO with varactor control, linear frequency tuning is limited to a specific range. The tuning becomes nonlinear and saturated beyond such range. Therefore, the VCO input from the phase detector preferably should not exceed this tuning range.

Another consideration for the VCO is phase noise, since it introduces an additional phase error into the loop and affects the locking. Phase noise is mainly concerned with the Q factor of the VCO. A LC oscillator with high Q is preferred in the VCO in order to suppress the phase noise, as well as increase the LC tank's oscillation amplitude.

An embodiment using an amplifier or a voltage attenuator in the loop will now be described. The loop filter may be implemented with any order low-pass filter, while a higher order low-pass filter usually provides better filtering characteristics, but with a more complex structure. In the design of a single PLL, the cutoff frequency of the loop filter is flexible to change in order to achieve the optimal damping factor based on the given detector gain and the gain constant of the VCO. However, as we can see in FIG. 3.2, the loop filter in the anti-parallel loop may also be used for data filtering. The choice for the selection of this cutoff frequency becomes very limited regarding this function, because good noise performance requires that the cutoff frequency is as small as possible to reduce the noise bandwidth of the receiver, while too small a bandwidth will cause inter-symbol interference (ISI). Thus the cutoff frequency of the loop filter is mainly determined by the data rate, and is not a variable for optimizing the damping factor. The cutoff frequency may be chosen at a frequency slightly higher than the data rate if RC low-pass filters are employed.

The problem mentioned above may be solved by, for example, introducing an amplifier (as in the case of the discrete component circuit implementation described above) or a voltage attenuator (as in the case of the IC implementation described below) to change the loop gain k, in order to meet the requirement for the optimal damping factor. The loop gain now has the form
k=kₐkₒk_{d} (5.5)
where kₐ is the added gain by the amplifier or the added loss by the voltage attenuator. The voltage attenuator may be implemented with, e.g., a resistor potentiometer. In this way, the damping factor may be optimized easily, without restricting other performance aspects of the three loop elements in equation (5.1) for this purpose.

Switch design will now be considered. As is well known, a field-effect transistor (FET) has advantages for implementation as a switch, such as nearly zero control current, low drain-source resistance in the “on” state, and high drain-source isolation in the “off” state. Besides those advantages, FETs are also preferred for the switches in the demodulator of the invention because they can transmit the detector output (around 0 V when the loop is locked) to the VCO with as low a voltage loss as possible, in order to achieve tight locking. For example, a suitable implementation for the switches of the demodulator is two N-type MOSFETs in symmetric configuration.

The comparator in the control circuit amplifies the small voltage-difference signals from the two loop detectors (0 and 2 V_{dc}) to the proper level for the control of the switch and the inverter. The inverter inverts the comparator output for the other switch so that only one switch is allowed to be turned on at any time. In some embodiments this inverter may be eliminated if the comparator is replaced by a fully differential comparator. For NMOSFET switches, the maximal control voltage should exceed the threshold voltage of the NMOSFET to turn on the device completely, while the minimal control voltage should be around zero or less to completely turn off the device.

The DC offset V_{dc} in each loop is another consideration in the design of the demodulator because it not only introduces a voltage difference between the two loops to ensure the proper operation of the control circuit and the switches, but also determines the signal amplitudes from the detectors (e.g., 0 and 2 V_{dc}). Thus the DC offset V_{dc} is a factor in the signal-to-noise ratio (S/N) of the detector outputs and affects system performance.

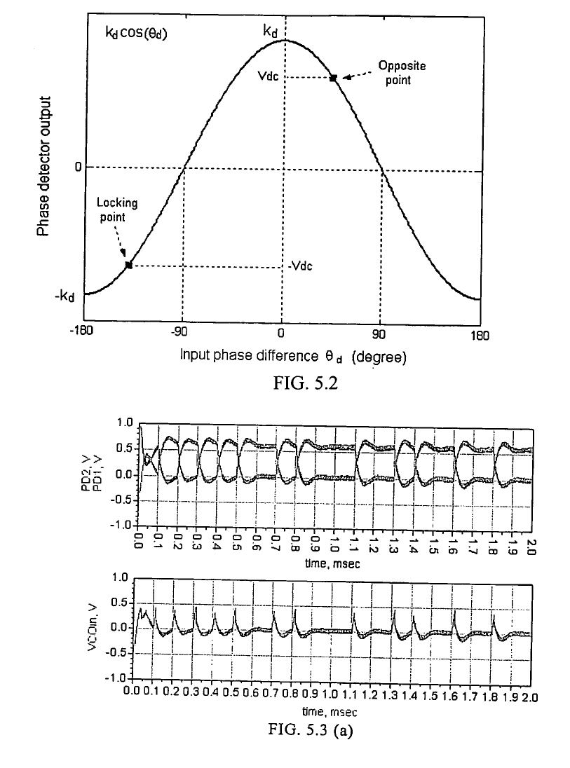

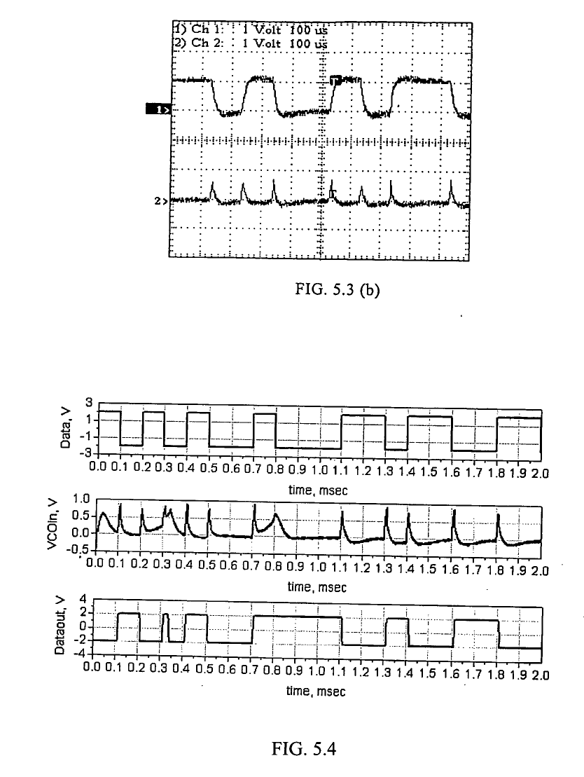

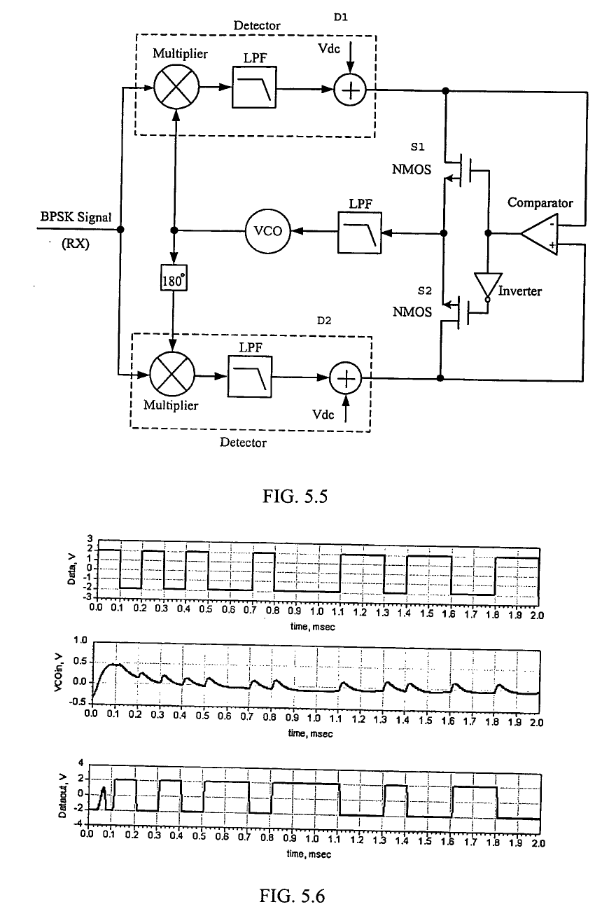

A bit error rate (BER) measurement on several DC offset values was carried out based on the discrete component circuit described above, in order to investigate the effect of DC offset on system performance. A pseudorandom bit sequence (PRBS) with a length of (2²³−1) was tested at 10 kbps in this measurement. The noise was generated from a noise source with the ability to generate additive white Gaussian noise (AWGN). The measured BER values versus the bit energy to noise density ratio (Eb/No) on different DC offsets is shown in FIG. 5.1, as well as a theoretical BER curve for BPSK. For the measurement results, the Eb/No was calculated from

$$Eb / No = \frac{S}{N} \cdot \frac{BW}{2 {f}_{B}} \qquad ( 5.6 )$$

where S/N is the input signal to noise ratio, BW is the input noise bandwidth (double sideband) of the demodulator and f_{B} is the bit rate. The theoretical curve is calculated by the probability of bit error for a BPSK demodulator

$$BER = Q ( \sqrt{\frac{2 {E}_{b}}{{N}_{0}}} ) = \frac{1}{2} erfc ( \sqrt{\frac{{E}_{b}}{{N}_{0}}} ) \qquad ( 5.7 )$$

As seen in FIG. 5.1, the measured BER curve is close to the theoretical curve when the DC offset is increased. The theoretical curve illustrates the ideal result available from a BPSK demodulator. The measurement result indicated that better BER performance could be achieved by use of a larger DC offset. BER performance of the BPSK demodulator may be further improved by differential coding/decoding to overcome data inversion in the re-locking process caused by sporadic noise.

Since the loop outputs before the voltage summers cannot exceed ±k_{d}, which is the maximal output range of the multiplier-type detector, the DC offsets fed to the voltage summers should not exceed k_{d}. Otherwise, the output of the multiplier-type detector would not compensate the DC offset to produce zero voltage for locking and therefore the VCO would lose locking. When the DC offset V_{dc} increases to the vicinity of the maximal value k_{d}, the slope of the detector output versus the phase differences of the two inputs decreases (see FIG. 5.2). The reduced slope decreases the detector gain, and as a result, increases the damping factor of the loop according to equation (5.1). A large damping factor makes the response of the loop slow (over-damped case), which makes it easier to lose locking.

Hence the vicinity of the maximal value is not suitable for the DC offset in this case. According to FIG. 5.2, the DC offset V_{dc} may be increased to about 70% of the maximal value (k_{d}) without much change of the slope; nevertheless, the headroom for the DC offset may be further reduced due to spikes at the switches' output. In the analysis discussed previously, two voltage levels were assumed at the outputs of the detectors, 0 V and 2 V_{dc}. With proper selection by the switches, only the lower voltage 0 V is fed to the VCO. This is not the case when the distortion effect of the loop filters on the detector outputs is considered. The loop filters have low-pass characteristics and smoothen the detector outputs (digital signals) as well as reject higher harmonics. This smoothing operation distorts the detector outputs by increasing their rise time and fall time. The outputs of the detector thus cannot be regarded to have only two voltage levels. As a result of the increased rise/fall time, there will be spikes on the output of the switches to the VCO. FIGS. 5.3(a) and (b) illustrate the existence of these spikes both in the simulations and the discrete component implementation. The spikes occurred at every data transition and reached one half of the DC offset V_{dc}. If not addressed, these spikes can alter the VCO phase and force the locking point to cross the negative peak on the left (shown in FIG. 5.2) to the other negative slope (not shown), and then lose locking if the DC offset was set higher than 0.5 k_{d}. The re-locking process may lock the VCO to the other phase of the received BPSK signal and induce an inversion on the data output. FIG. 5.4 shows spike-induced data inversions in the simulations with DC offsets of 0.7 V (k_{d}=1 V), where the inversions occur at 0.3 ms and 0.8 ms.

A further embodiment using another LPF will now be described. The spikes at the VCO input might cause inversion of the data output when the DC offset goes over one half of k_{d}. This limits increasing the DC offset value to provide better BER performance. However, introducing another low-pass filter after the switches can suppress the spikes. This is shown in the demodulator of FIG. 5.5. The cutoff frequency of this filter determines how much the spike amplitude can be reduced, and would typically be set to lower than the data rate (maximal repeating frequency of the spike). This configuration can significantly suppress the spikes and extend the headroom of the DC offset to allow better BER performance. The introduced low-pass filter may be seen as part of the loop filter in calculating loop parameters such as the damping factor in equation (5.1). The loop noise bandwidth, which is concerned with the loop gain k and the cutoff frequency of the loop filter, is required to be larger than the phase noise bandwidth of the carrier generator in the transmitter in order to make the loop fast enough to acquire the phase of the carrier with noise, so there is a lower limit for the cutoff frequency of the introduced LPF.

FIG. 5.6 shows the simulation result based on the demodulator of FIG. 5.5, where the DC offset was 0.7 V (k_{d}=1 V) and the cutoff frequency of the introduced LPF was 5 kHz. The loop gain was re-arranged to optimize the damping factor according to the introduced LPF compared to FIG. 5.4. It is noted that the spikes were suppressed by the LPF and there was no inversion induced by the spikes (the demodulated data kept its original inversion for cos(θₑ)>0 case). In this way, the headroom for the DC offsets may be increased.

Except for the distortion of the loop filters, larger spikes may also come from noise. If the DC offsets are set close to the k_{d}, large spikes from the noise may cause sporadic inversions of the demodulator output. These spikes may also be suppressed by addition of the third LPF as described above.

2.4. Monolithic Microwave Integrated Circuit (MMIC) Implementation

2.4.1. MMIC Simulation

A simulation of an integrated circuit (IC) implementation of the anti-parallel loop BPSK demodulator of the invention, including embodiments of IC implementations of certain parts of the demodulator, will now be described. A compact structure of the demodulator can be achieved by making full use of current IC technologies, such as an integrated Gilbert multiplier, differential VCO and CMOS switches.

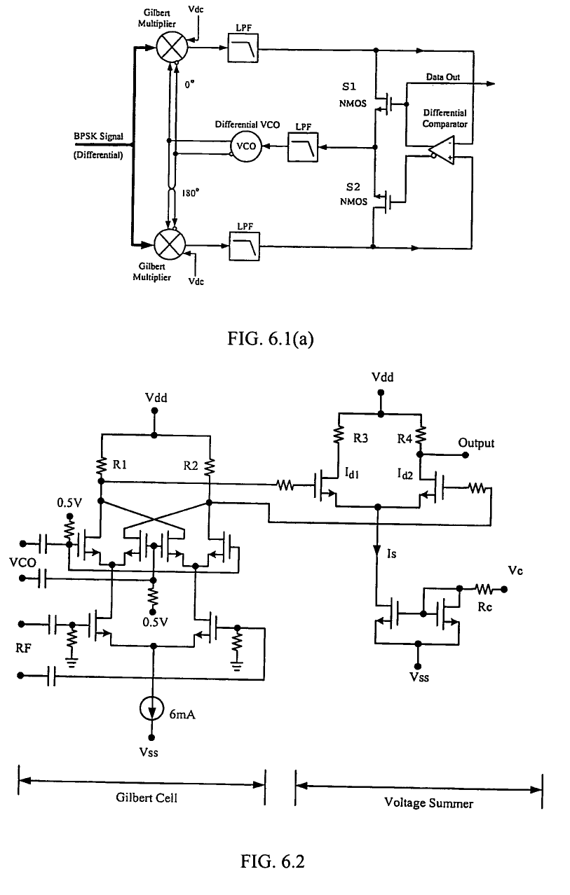

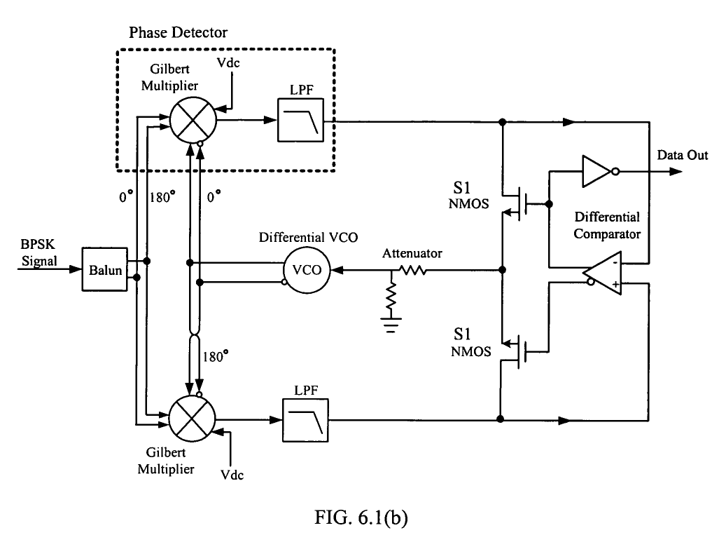

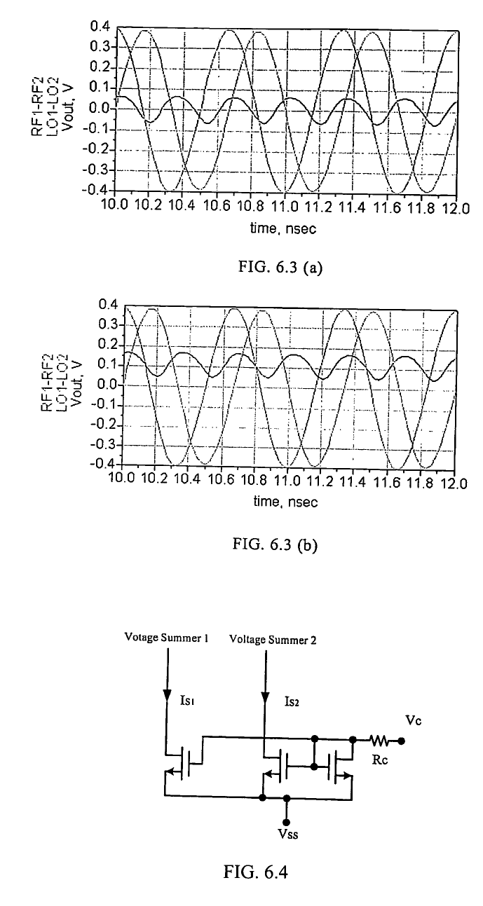

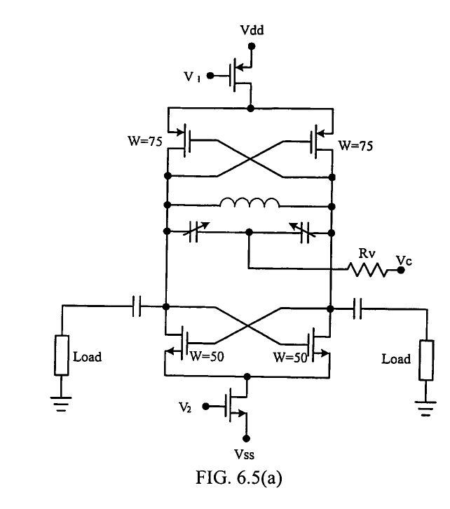

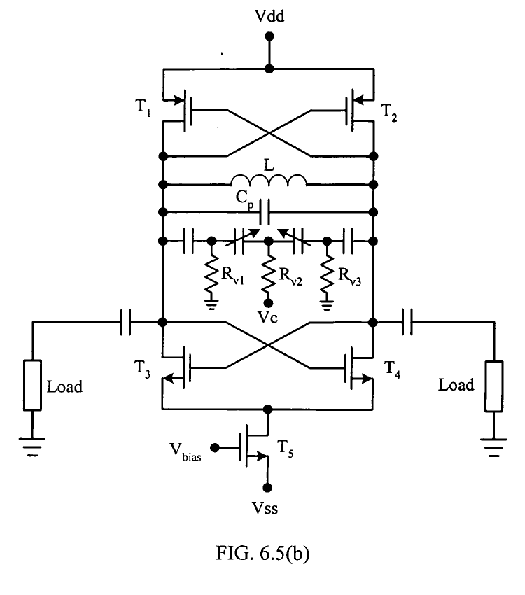

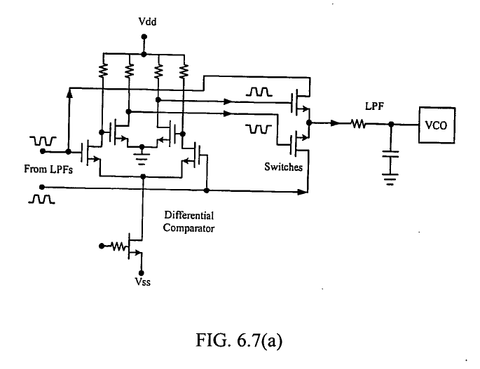

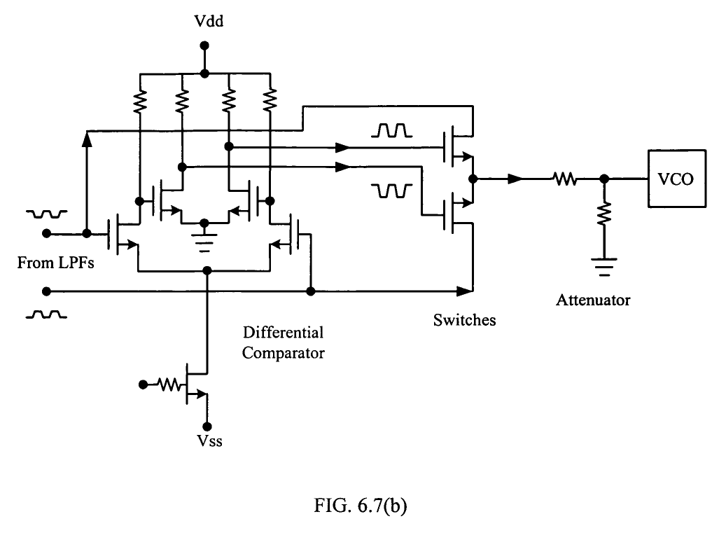

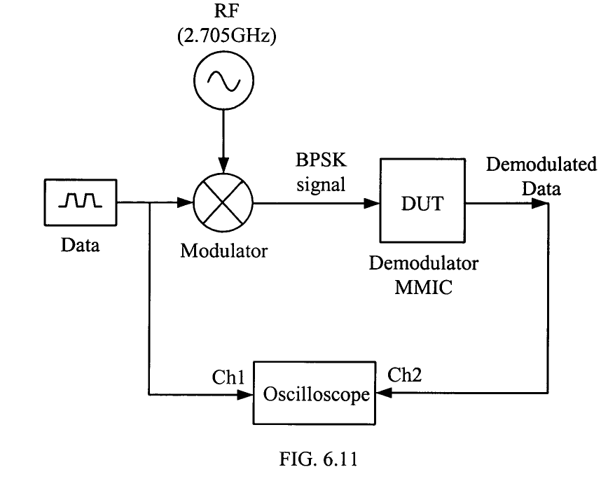

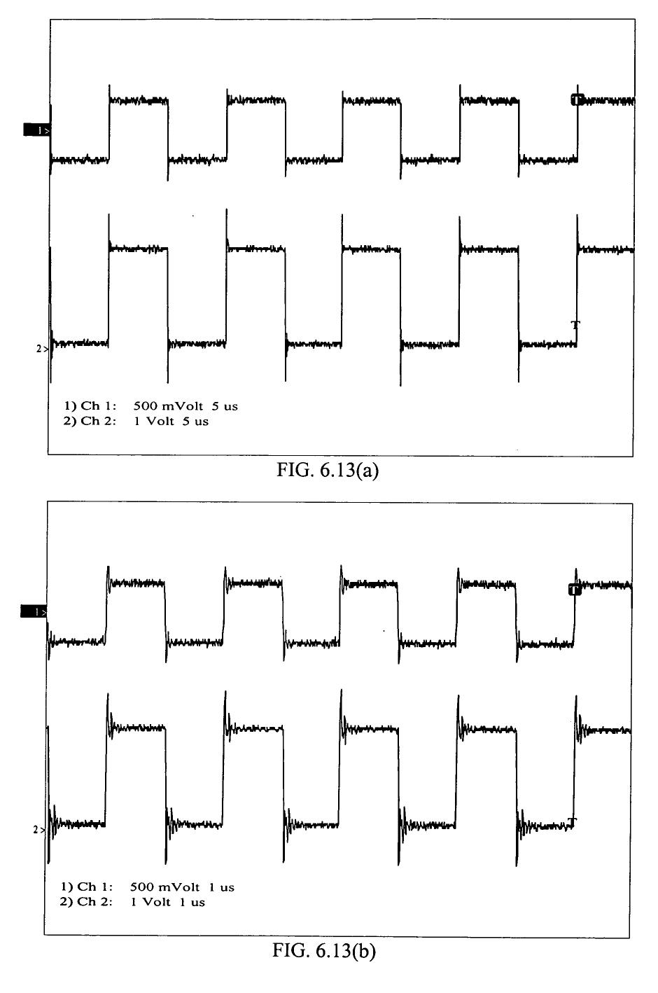

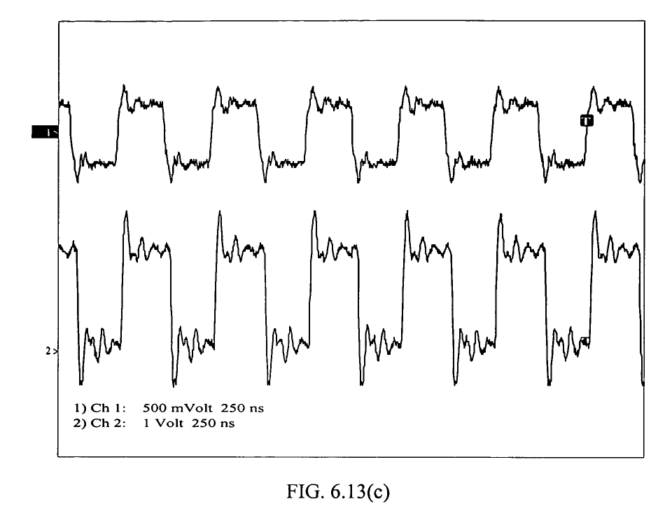

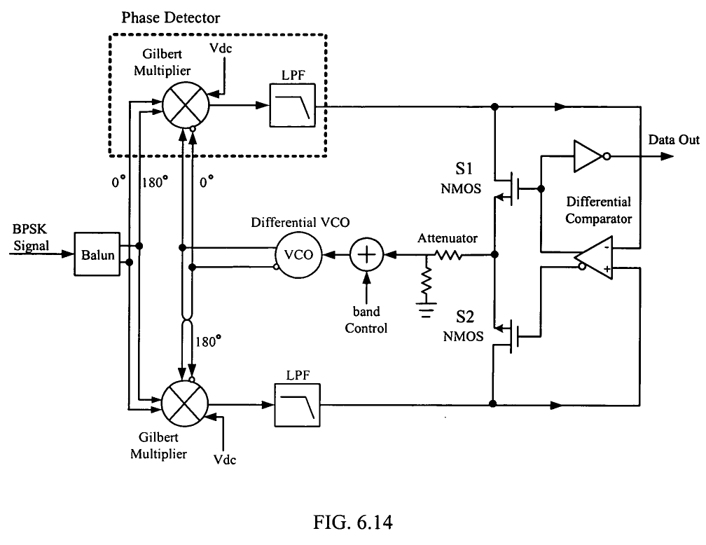

A compact design of the demodulator suitable for IC implementation, which is based on available integrated-circuit elements, is shown in FIG. 6.1(a). In this embodiment, the multipliers for the detectors were implemented using two Gilbert-cell mixers, which are usually used for analog phase detectors. Their differential input signals come from a differential VCO. The differential signal lines (two lines) from the VCO to the lower multiplier were twisted once before they entered the multiplier, by which a 180° phase shift is produced. This can be done easily in IC implementation and thus eliminates the use of other phase shifting devices. The demodulator makes the best of this configuration to reduce the system complexity. The voltage summers for the DC offsets were integrated into the Gilbert multipliers in FIG. 6.1(a). The switches were implemented with two N channel MOSFETs as demonstrated in the experiments and their control signals were from a differential comparator, thus the inverter was not required. The two loop filters may be any order low-pass filters while a RC low-pass filter is the simplest. The third LPF at the VCO input may also be realized with a RC low-pass filter. More details about the above designs based on the TSMC 0.18 um CMOS models will now be discussed.

As a multiplier-type mixer, the Gilbert cell theoretically has perfect isolation among the three signals LO, RF and IF, due to its balanced structure. Thus the Gilbert cell does not require extra filters as are required for isolation in other mixers. These features make it very suitable for the voltage multiplier in the analog phase detector. FIG. 6.2 shows a Gilbert multiplier with a voltage summer for the loop DC offset.

In FIG. 6.2, the multiplier uses a common Gilbert cell topology. The bias current for the Gilbert cell is realized with a current mirror circuit. The LO signal coming from the differential VCO and the received RF signal are fed to the Gilbert multiplier, mixed with each other and output to the following voltage summer. The voltage summer may be realized using a differential pair biased by a current mirror circuit. The control voltage of the current mirror V_{C} is for the loop DC offset and it controls the current I_{S} flowing through the differential pair and the I_{S} relies on V_{C} by

$${I}_{S} = \frac{{V}_{C} - {V}_{SS}}{{R}_{C}} \qquad ( 6.1 )$$

Then the DC offset or the DC voltage V_{dc} at the outputs of the voltage summer is related to the control voltage V_{C} by

$${V}_{d c} = {V}_{dd} - {I}_{d 2} {R}_{4} = {V}_{dd} - \frac{Is}{2} {R}_{4} = - \frac{{R}_{4}}{2 {R}_{C}} ( {V}_{C} - {V}_{SS} ) + {V}_{dd} \qquad ( 6.2 )$$

By choosing 2 as the ratio of the above resistors R₄ and R_{C}, the voltages V_{dd} and V_{SS} are cancelled if V_{dd}=−V_{SS}, resulting in
V_{dc}=−V_{C} (6.3)
Thus the output of the voltage summer will sum the signals from the Gilbert cell with the inversion of the control signal V_{C}. In practice, in addition to the DC mixing product, the output from the Gilbert cell also contains a DC bias which needs to be compensated at the voltage summer, the above resistor ratio preferably is not set to 2. Therefore, there is a coefficient less than 1 before the V_{C} in equation (6.3).

In simulations performed using the TSMC 0.18 um CMOS models, the frequencies of the LO signal and the RF signal were 1.5 GHz, which is at L-band of INMARSAT systems and the GPS system. Their amplitudes were set to 0.4 V. Larger inputs would cause signal distortion as observed in the simulations. FIG. 6.3 shows the inputs of the Gilbert multiplier (the two large signals) and the output of the voltage summer (the small signal) at 0 V and 0.1 V DC offsets, respectively. The two large signals illustrate the RF signal and the LO signal, and they were set to 90′ phase shifted from each other (orthogonal), so the multiplication of these two signals yields no DC product as illustrated in FIG. 6.3(a), in which no DC offset was added at the voltage summer. FIG. 6.3(b) shows the voltage summer's output when there is a DC offset of 0.1 V introduced by its control voltage V_{C}. The phase difference between the two multiplier inputs is maintained at 90° for the comparison. The detector gain accompanying this multiplier is 60 mV/rad, so the above DC offsets should be adjusted accordingly.

Since the two DC offsets at the dual loop are the same, the current mirrors of the two voltage summers may be combined to share a single DC offset, as shown in FIG. 6.4. This configuration not only simplifies the circuitry for the DC offsets, but also reduces any possible difference between the two DC offsets, which may result from variation introduced during IC manufacturing.

The topology of the differential VCO may be selected from known designs such as, for example, cross-coupled and differential Colpitts. The cross-coupled topology was chosen due to its relatively good phase noise and ease of implementation. However, other topologies may also be used.

FIG. 6.5(a) shows an exemplary complementary cross-coupled differential VCO based on MOSFETs and MOS varactors. Compared to the NMOS-only cross-coupled topology, this complementary version using both PMOS and NMOS can provide higher transconductance for a given current and lower noise due to its symmetric rise time and fall time on the output signal. A width ratio for two types of MOSFETs should be selected correctly in order to compensate for the speed discrepancy due to different mobility and threshold voltages of two transistors. Two transistors (one PMOS at the top and one NMOS at the bottom) are used for the current bias, instead of only one NMOS for this purpose in other works. This symmetric configuration can remove the DC voltage applied to the varactors from the supplies in order to achieve direct varactor control with only a high value resistor R_{V}, as illustrated in FIG. 6.5(a); otherwise it would require an extra DC offset for varactor control. The high value resistor R_{V} can provide isolation between the RF path and the external control circuit. As discussed previously, a large input signal is not suitable for the Gilbert multiplier, so maximal output from the VCO was not pursued in this embodiment. This simplifies other issues in the design of the VCO, such as requirements of output capacity, Q factor of the LC oscillator and signal distortion.

A simulation circuit of this complementary differential VCO was built based on the 1.8 V models of transistors and MOSFET varactors in TSMC 0.18 um CMOS. According to their parameters, the width ratio of PMOS and NMOS FETs was set to about 1.5. A 5 nH inductor with a Q factor of 6.7 was used in the LC oscillator, which is consistent with the parameters provided by the TSMC for their spiral inductors. The centre frequency of the LC oscillator was around 1.5 GHz. The simulation results showed that the two outputs offset from each other with very small distortion and thus met the requirement for the differential signal. The VCO linear tuning range was about 1.3 to 1.9 GHz and its gain constant kₒ at zero control voltage was calculated to be (0.9×2π) Grad/sec/volt.

For a single PLL based on the above values of the detector gain k_{d} and the VCO gain constant kₒ, a loop filter with a cutoff frequency of 106 MHz would be required to achieve the optimal loop damping factor (0.7). However, for a demodulator with a data rate lower than 106 Mbps, it will need a voltage attenuator, such as a potentiometer, at the input of the VCO to lower the loop gain. Hence, the cutoff frequency of the loop filter can be decreased for the data filtering purpose without affecting the damping factor. For instance, if a loop filter with a 14 MHz cutoff frequency is used at each loop for a data rate of 10 Mbps (GPS P-code uses 10.23 Mbps), a potentiometer with a voltage ratio of 7.6 or (17.6 dB loss) is required for the optimal damping factor. An attenuator with larger loss will be required if a lower data rate is used for this demodulator system. The third LPF at the input of VCO may also require a lower loop gain due to its effect on the cutoff frequency of the loop filter. This has been discussed previously.

As discussed above, two N type MOSFETs in a symmetric configuration are suitable to implement the switches. The two offset control signals of these switches may come from a differential comparator. FIG. 6.7(a) shows an example design of the NMOS switches and the differential comparator. The comparator contains a differential pair and two common-source amplifiers. In the comparator, the two inputs coming from the detector outputs are amplified to proper level for control of the switches. The differential pair and the following two amplifiers may be biased to their threshold region to achieve high gain, and thus high sensitivity for the comparator. With the control of the switching signal from the comparator, the smaller voltage output (zero volt when locked) in the two outputs of the detectors are selected by the switches and applied to the VCO before passing a LPF.

In simulations of this circuit based on TSMC 0.18 um CMOS models, the inputs of the differential comparator were two offset pulses switching between 0 V and 40 mV, and the equivalent data rate was 10 Mbps. The amplitudes of the pulses were increased to between 0.1 V and 1.1 V by the comparator. The smaller voltage output (0 V) in the two inputs was successfully selected and presented at output of the NMOS switches, but with spikes at the transitions of the input signals. As mentioned previously, these spikes are related to the smoothing operation of loop filters on the digital outputs of the detectors, and introducing a LPF after the switches can reduce the amplitude of these spikes and minimize their effect on the VCO. The spikes were significantly suppressed in the simulations by the introduction of an LPF with a cutoff frequency of 4.4 MHz.

2.4.2. MMIC Fabrication and Testing

A MMIC embodiment of the anti-parallel loop BPSK demodulator according to the invention was fabricated using TSMC 0.18 μm CMOS technology, and tested. A compact structure of the demodulator was achieved by making full use of current IC techniques, including an integrated Gilbert multiplier, a differential VCO, and CMOS switches, as in the simulation above, with differences as indicated below (see FIG. 6.1(b)). The fabricated demodulator had a carrier frequency of 2.7 GHz and a tested data rate up to 5 Mbps. The multipliers for the detectors were implemented with two Gilbert-cell multipliers, as described in the above MMIC simulation. One of the differential input signals was obtained from a balun circuit at the demodulator input, which transformed the received unbalanced BPSK signal into a differential signal as required by the Gilbert-cell multipliers. The other of the differential input signals was obtained from a differential VCO. The differential signal lines (two lines) from the VCO to the lower multiplier were twisted once before they entered the lower multiplier (i.e., by a differential twisted pair), by which a 180° phase shift was easily produced and thus eliminated the need for other phase shifting devices. The voltage summers for the DC offsets were integrated into the Gilbert multipliers as shown in FIG. 6.1(b). The switches S1, S2 were implemented with two N-type MOSFETs and their control signals were from a differential comparator, thus the inverter for the control was not required. The two loop filters may be any order low-pass filters. However, a RC low-pass filter is the simplest and hence was chosen for this implementation. A voltage attenuator was placed at the VCO input to change the loop gain in order to attain the optimal damping factor. A third LPF associated with the VCO was not included so as to simplify the implementation. An additional inverter was introduced at the data output so that the differential comparator output could be isolated from the data output.

Since the two DC offsets of the dual loop are the same, the current mirrors of the two voltage summers were combined to share a single DC offset, as shown in FIG. 6.4. This configuration not only simplified the circuitry for the DC offsets, but also reduced the possibility of any difference between the two DC offsets, which can result from variation introduced during IC manufacturing. The two current mirrors used for the multipliers in the demodulator were also combined in the same way.

FIG. 6.5(b) shows the complementary cross-coupled differential VCO using MOSFETs and MOS varactors, which worked at 2.7 GHz. Compared to the NMOS-only cross-coupled topology, this complementary version using both PMOS and NMOS can provide higher transconductance for a given current and lower noise due to its symmetric rise time and fall time on the output signal. A width ratio for two types of MOSFETs was selected to compensate for the speed discrepancy resulting from the different mobility and threshold voltages of the two types of transistors. Note that in a further embodiment, a single NMOSFET may be used at the bottom of the circuit to control the current, resulting in an asymmetrical structure. One transistor (i.e., T₅ in FIG. 6.5(b)) was placed at the bottom for the tail current bias. The MOS varactor had a large tuning ratio of 3, which could cause a large gain constant for the VCO if it was directly used as the tuning capacitor, so a capacitor Cₚ was introduced in parallel with the two varactors to lower the gain constant. A gain constant of 126 M rad/sec/volt was selected for this VCO implementation. The high-value resistors (Rᵥ₁, Rᵥ₂, and Rᵥ₃) were used to provide isolation between the RF path and the ground or the VCO input. Maximal output from the VCO was not pursued in this embodiment because too large VCO output would overdrive the Gilbert multipliers. This simplified other issues in the design of the VCO, such as requirements of output capacity, Q factor of the LC oscillator, and signal distortion.

In the IC implementation, two RC low-pass filters with a cutoff frequency of f_{L}=33 MHz were used for the loop filter, which in theory work for a data rate up to 20 Mbps. Based on the detector gain k_{d}=1.2 V/rad, the VCO gain constant kₒ=126 Mrad/sec/volt, and the loop filter cutoff frequency f_{L}=33 MHz, a voltage attenuator using a potentiometer was placed at the input of the VCO to optimize the loop damping factor to about 0.7, according to equation (5.1).

As discussed previously, two N-type MOSFETs in symmetric configuration are suitable to implement the switches. The two offset control signals of these switches may come from, for example, a differential comparator. FIG. 6.7(b) shows such a design using NMOS switches and a differential comparator. The comparator contained a differential pair and two common-source amplifiers. In the comparator, the two inputs coming from the detector outputs were amplified to an appropriate level for control of the switches. The differential pair and the following two amplifiers were biased to their threshold regions to achieve high gain, and thus high sensitivity for the comparator. A simulation of this comparator gave a voltage gain of 25. With proper control of the switching signal from the comparator, the smaller voltage output (0 V when locked) at the two outputs of the detectors was selected by the switches and applied to the VCO through the voltage attenuator described previously.

An MMIC demodulator was fabricated using the IC components described above and verified in using Advanced Design System (ADS) electronic design automation software). The circuit layout was designed using Cadence and the MMIC was fabricated using TSMC 0.18 μm CMOS technology. The free running frequency of the VCO in the MMIC was first measured to be about 2.7 GHz. A measurement setup was created to test the demodulation performance of the MMIC demodulator, as shown in FIG. 6.11. The BPSK signal for the test was generated in the same way as in the previous simulations and implemenations. A microwave BPSK modulator modulated symmetric digital data (−0.5˜0.5 V) on a RF carrier at about 2.7 GHz to generate the BPSK signal. A square wave was used for the digital data. The BPSK signal was fed to the MMIC demodulator and the demodulated data was extracted from the demodulator using RF probes, and the data was sent to an oscilloscope for comparison with the original digital data. FIG. 6.13(a), (b) and (c) show the measurement results at three data rates, 200 Kbps, 1 Mbps, and 5 Mbps, respectively. These results were captured from the oscilloscope and each shows the original data in Channel 1 (the upper waveform) and the demodulated data in Channel 2 (the lower waveform). Comparison of the two waveforms in each figure shows clearly that all the data were demodulated properly. The input RF frequency range was from 2.7030 to 2.7077 GHz with input power of −13.5 dBm in the measurement, while the minimum required BPSK signal input power was −20 dBm (measured at carrier frequency of 2.705 GHz), which is the sensitivity of the MMIC demodulator. The total DC power consumption of the MMIC demodulator was 151 mW.

2.4.3. Design Methodology

Based on the considerations discussed above, a preferred IC design methodology may be summarized as:

1. Design the multipliers and the voltage summers. The inputs of the multipliers require matching circuits at the carrier frequency.

2. Design the VCO at the desired centre frequency. A linear tuning range is preferred. The output amplitude of the VCO meets the requirement of the multiplier input.

3. Design the loop filters. According to the data rate, choose the appropriate cutoff frequency, usually at a frequency equal to or a little higher than the data rate.

4. Design the low-pass filter at the input of the VCO to suppress the spikes. This step is optional. The cutoff frequency may be set to lower than the data rate. At the same time, the total noise bandwidth of the loop should be larger than the phase noise bandwidth of the carrier generator in the modulator. Recalculation of the total cutoff frequency of each loop will be required for next step if this step is chosen.

5. Optimize the loop damping factor to 0.7 by introducing an amplifier or an attenuator into the loop according to equation (5.1) and equation (5.4). The cutoff frequency ω_{L} may require adjustment by considering the contribution of the introduced LPF at the input of the VCO. The amplifier or attenuator may be placed at the input of the VCO.

6. Choose as large a DC offset as the system can tolerate to achieve the best system performance. The offset determines the two loop outputs.

7. Design the NMOSFET switches and their control circuit. The control circuit may be realized by a fully differential comparator in an IC implementation. The required comparator gain is determined by the difference between the loop output amplitude and the desired control signal amplitude of the switches.

2.5. Multi-Band Demodulation System Example

In a multiple-band communication system, a receiver should be able to work at all frequency channels with some extra frequency tuning elements. Receivers re-use most of their elements in multi-band operations in order to simplify the circuitry and save cost. The cost of expanding a system to a multi-band system depends on how many elements need frequency tuning and how easy it is to implement such tuning.

As can be seen in the various embodiments of the demodulator of the invention, only the VCO requires frequency tuning for multi-band purposes. More specifically, only the centre frequency of the LC oscillator in the VCO needs to be tuned. Thus a multi-band BPSK demodulator system can be realized from the demodulator embodiments described herein. FIG. 6.14 shows a diagram of an example of a multi-band demodulator. Compared to the single-band version, another voltage summer is introduced at the input of the VCO to tune the VCO centre frequency accordingly. The available bandwidth of this multi-band system is thus determined by the linear frequency tuning range of the VCO. In the MMIC embodiment described above, the VCO has a linear tuning range of about 80 MHz. A larger tuning range may be achieved by, for example, reducing the parallel capacitor Cₚ (increasing the varactors accordingly) in the VCO of FIG. 6.5. The voltage attenuator may also need to be adjusted as appropriate to maintain the desired damping factor, since the gain constant of the VCO varies with its frequency tuning range.

The contents of all cited publications are incorporated herein by reference in their entirety.

### EQUIVALENTS

It will be understood by those skilled in the art that this description is made with reference to preferred embodiments and that it is possible to make other embodiments employing the principles of the invention which fall within its spirit and scope as defined by the following claims. For example, it is to be recognized that the MMIC implementation described herein is an example only and other topologies could be created to implement the embodiments described herein, each such implementation falling within one or more of the following claims. Similarly, other embodiments could be created by persons skilled in the art based on the principles described herein, which embodiments can be implemented in one or more IC topologies. Such embodiments will also fall within the following claims.

1. A BPSK demodulator for use with a BPSK signal, the demodulator comprising:
a first phase-locked loop for locking to the BPSK signal; and
a second phase-locked loop for locking to the BPSK signal, which second phase-locked loop locks to the BPSK signal at a 180° phase difference from the first phase-locked loop;
wherein the first phase-locked loop and the second phase-locked loop are selected such that the first phase-locked loop is in lock at 0° and the second phase-locked loop is in lock at 180°.

2. The demodulator of claim 1, further comprising a selection network for selection of the first and second phase-locked loops.

3. The demodulator of claim 2 wherein the selection network comprises two switches, a comparator, and an inverter.

4. The demodulator of claim 1, wherein the first and second phase-locked loops each further comprise a multiplier and a voltage controlled oscillator.

5. The demodulator of claim 1, wherein the first and second phase-locked loops each further comprise a low pass filter and a summing circuit.

6. The demodulator of claim 1, wherein the first and second phase-locked loops are interconnected to share a single voltage controlled oscillator.

7. The demodulator of claim 6, further comprising an automatic gain control circuit front end.

8. The demodulator of claim 2, wherein the selection network further comprises a low-pass filter.

9. The demodulator of claim 6, further comprising a voltage summer at the VCO front end.

10. The demodulator of claim 6, wherein the first and second phase-locked loops each further comprise an amplifier.

11. The demodulator of claim 6, wherein the first and second phase-locked loops each further comprise an attenuator.

12. The demodulator of claim 6, implemented in an integrated circuit.

13. The demodulator of claim 5, wherein a DC offset is introduced into the phase-locked loops by the summing circuit such that the phase-locked loops have different voltage outputs.

14. A method of demodulating a BPSK signal, comprising:
providing a first phase-locked loop for locking to the BPSK signal;
providing a second phase-locked loop for locking to the BPSK signal, which second phase-locked loop locks to the BPSK signal at a 180° phase difference from the first phase-locked loop; and
selecting the phase-locked loops such that the first phase-locked loop is in lock at 0° and the second phase-locked loop is in lock at 180°.

15. The method of claim 14, wherein selecting the phase-locked loops further comprises comparing the BPSK signal detected by each of the phase-locked loops to determine the phase of the BPSK signal.

16. The method of claim 15, wherein selecting the phase-locked loops further comprises opening and closing respective switches in accordance with the determined phase.

17. The method of claim 14, further comprising detecting the phase of the BPSK signal in each of the phase-locked loops by multiplying the BPSK signal and a locking signal produced by a voltage controlled oscillator.

18. The method of claim 17, wherein detecting the phase further comprises passing the multiplied signal through a low pass filter and a summing circuit.

19. The method of claim 17, further comprising producing the locking signal for both detectors using a single voltage controlled oscillator.

20. The demodulator of claim 2, wherein the selection network may also comprise two switches and a differential comparator.

21. The demodulator of claim 5, wherein the summing circuits are before or after the low pass filters.

22. The demodulator of claim 6, wherein the first and second phase-locked loops share a single attenuator.

23. The demodulator of claim 5, wherein the summing circuits comprise a differential pair controlled by a current mirror.

24. The demodulator of claim 1, wherein the 180 degree phase is provided by a twisted pair.

25. The demodulator of claim 13 wherein the summing circuits share a current mirror to combine the two DC offsets.

26. The demodulator of claim 4, wherein the two multipliers share a current mirror.

27. The demodulator of claim 6, wherein the VCO comprises a parallel capacitor and varactor.

28. The method of claim 19, further comprising optimizing the loop damping factor by adjusting the VCO gain constant.
